(19) United States
(12) Patent Application Publication
(10) Pub. No.: US 2023/0392053 A1
(43) Pub. Date: Dec. 7, 2023

(54) POLYMER FILM WITH ADHESIVE LAYER, LAMINATE, AND METHOD FOR PRODUCING LAMINATE

(71) Applicant: FUJIFILM Corporation, Tokyo (JP)

(72) Inventors: Genya TANAKA, Shizuoka (JP); Hirotaka KITAGAWA, Shizuoka (JP)

(73) Assignee: FUJIFILM Corporation, Tokyo (JP)

(21) Appl. No.: 18/451,815

(22) Filed: Aug. 17, 2023

Related U.S. Application Data
(63) Continuation of application No. PCT/JP2022/007681, filed on Feb. 24, 2022.

(30) Foreign Application Priority Data
Feb. 24, 2021 (JP) 2021-027803

(51) Int. Cl. C09J 7/35; C09J 7/22; C09J 5/06; H05K 1/03

(52) U.S. Cl. CPC C09J 7/35; C09J 7/22; C09J 5/06; H05K 1/036; C09J 2301/304; C09J 2479/08; C09J 2400/226; C09J 2400/166

(57) ABSTRACT

An object of the present invention is to provide a polymer film with an adhesive layer, capable of forming a laminate in which a metal layer formed of a metal foil that is arranged on and compression-bonded to the adhesive layer is excellent in adhesiveness, and a portion other than the metal layer has a low dielectric loss tangent. Another object of the present invention is to provide a laminate obtained by using the polymer film with an adhesive layer; and a method for producing the laminate. A polymer film with an adhesive layer according to an embodiment of the present invention has a polymer film including a polymer having a standard dielectric loss tangent of 0.005 or less and the adhesive layer arranged on the polymer film, in which in a case where a surface of the polymer film on a side of the adhesive layer is measured by X-ray photoelectron spectroscopy, an atomic ratio of oxygen atoms to carbon atoms is 0.27 or more, the adhesive layer includes a compound having a reactive group, the adhesive layer has a thickness of 1 μm or less, and the adhesive layer has a post-curing elastic modulus of 0.8 GPa or more.

### CROSS-REFERENCE TO RELATED APPLICATIONS

This application is a Continuation of PCT International Application No. PCT/JP2022/007681 filed on Feb. 24, 2022, which claims priority under 35 U.S.C. § 119(a) to Japanese Patent Application No. 2021-027803 filed on Feb. 24, 2021. The above applications are hereby expressly incorporated by reference, in their entirety, into the present application.

### BACKGROUND OF THE INVENTION

### 1. Field of the Invention

The present invention relates to a polymer film with an adhesive layer, a laminate, and a method for producing the laminate.

### 2. Description of the Related Art

Higher frequencies and broadband than ever before have been used in a 5^{th} generation (5G) mobile communication system, which is considered to be next-generation communication technology. Therefore, as a substrate film for a circuit board for a 5G mobile communication system, those having characteristics of a low dielectric constant and a low dielectric loss tangent are in demand, and development of substrate films using various materials is in progress. One of such substrate films is a liquid crystal polymer film. The liquid crystal polymer (LCP) film has a lower dielectric constant and a lower dielectric loss tangent than films commonly used in 4^{th} generation (4G) mobile communication systems, such as a polyimide film and a glass epoxy film.

For example, JP2019-112642A discloses an adhesive film with a substrate, in which a thermosetting adhesive composition containing a vinyl compound having a specific structure, a maleimide resin, and a thermoplastic elastomer is formed on a liquid crystal polymer film.

### SUMMARY OF THE INVENTION

Alaminate having a polymer film having a low dielectric loss tangent and a metal layer is used in, for example, production of a circuit board. In such a laminate, in a case where peeling of the metal layer from the polymer film occurs, the reliability of the circuit board is impaired. Therefore, it is required to improve the adhesiveness between the polymer film and the metal layer.

As a method for improving the adhesiveness between the polymer film and the metal layer, a method in which a layer (adhesive layer) that can be obtained by using an adhesive composition as described in JP2019-112642A is arranged between a polymer film and a metal layer is conceivable.

The present inventors have manufactured a polymer film with an adhesive layer with reference to JP2019-112642A, in which the adhesive layer and a metal foil were compression-bonded to each other. The present inventors have found that the adhesiveness of a metal layer formed from the metal foil is good, but the dielectric loss tangent of a portion other than the metal layer included in the laminate is increased, and thus, there is room for improvement.

The present invention has been made in view of the circumstances, and has an object to provide a polymer film with an adhesive layer, capable of forming a laminate, in which in a case where a metal foil is arranged on and compression-bonded to the adhesive layer, the adhesiveness of a metal layer formed from the metal foil is excellent and the dielectric loss tangent of a portion other than the metal layer is low.

In addition, another object of the present invention is to provide a laminate obtained by using the polymer film with an adhesive layer and a method for producing the laminate.

The present inventors have conducted intensive studies to accomplish the objects, and as a result, they have found that the objects can be accomplished by the following configurations.

[1]

A polymer film with an adhesive layer, comprising:
a polymer film including a polymer having a dielectric loss tangent under conditions of a temperature of 23° C. and a frequency of 28 GHz of 0.005 or less; and
the adhesive layer arranged on the polymer film,
in which in a case where a surface of the polymer film on a side of the adhesive layer is measured by X-ray photoelectron spectroscopy, an atomic ratio of oxygen atoms to carbon atoms is 0.27 or more,
the adhesive layer includes a compound having a reactive group,
the adhesive layer has a thickness of 1 μm or less, and
the adhesive layer has a post-curing elastic modulus of 0.8 GPa or more.

[2]

A polymer film with an adhesive layer, comprising:
a polymer film having a dielectric loss tangent under conditions of a temperature of 23° C. and a frequency of 28 GHz of 0.005 or less; and
the adhesive layer arranged on the polymer film,
in which in a case where a surface of the polymer film on a side of the adhesive layer is measured by X-ray photoelectron spectroscopy, an atomic ratio of oxygen atoms to carbon atoms is 0.27 or more,
the adhesive layer includes a compound having a reactive group,
the adhesive layer has a thickness of 1 μm or less, and
the adhesive layer has a post-curing elastic modulus of 0.8 GPa or more.

[3]

The polymer film with an adhesive layer according to [1] or [2],
in which the reactive group is at least one group selected from the group consisting of an epoxy group, an oxetanyl group, an isocyanate group, an acid anhydride group, a carbodiimide group, an N-hydroxyester group, a glyoxal group, an imidoester group, an alkyl halide group, and a thiol group.

[4]

The polymer film with an adhesive layer according to any one of [1] to [3],
in which the adhesive layer has a post-curing dielectric loss tangent under the conditions of a temperature of 23° C. and a frequency of 28 GHz of 0.01 or less.

[5]

The polymer film with an adhesive layer according to any one of [1] to [4],
in which the adhesive layer has a post-curing elastic modulus of 1.2 GPa or more.

[6]

The polymer film with an adhesive layer according to any one of [1] to [5],
in which the adhesive layer further includes a binder resin.

[7]

The polymer film with an adhesive layer according to any one of [1] to [6],
in which the compound having a reactive group has three or more of the reactive groups.

[8]

A laminate comprising:
a polymer film including a polymer having a dielectric loss tangent under conditions of a temperature of 23° C. and a frequency of 28 GHz of 0.005 or less;
a resin layer arranged on the polymer film; and
a metal layer arranged on the resin layer,
in which in a case where a surface of the polymer film on a side of the resin layer is measured by X-ray photoelectron spectroscopy, an atomic ratio of oxygen atoms to carbon atoms is 0.27 or more,
the resin layer has a thickness of 1 μm or less, and
the resin layer has an elastic modulus of 0.8 GPa or more.

[9]

A laminate comprising:
a polymer film having a dielectric loss tangent under conditions of a temperature of 23° C. and a frequency of 28 GHz of 0.005 or less;
a resin layer arranged on the polymer film; and
a metal layer arranged on the resin layer,
in which in a case where a surface of the polymer film on a side of the resin layer is measured by X-ray photoelectron spectroscopy, an atomic ratio of oxygen atoms to carbon atoms is 0.27 or more,
a thickness of the resin layer is 1 μm or less, and
the resin layer has an elastic modulus of 0.8 GPa or more.

[10]

The laminate according to [8] or [9],
in which a maximum height Rz of a surface of the metal layer on a side of the resin layer is 0.6 to 2.0 μm.

[11]

The laminate according to any one of [8] to [10],
in which the resin layer has a dielectric loss tangent under the conditions of a temperature of 23° C. and a frequency of 28 GHz of 0.01 or less.

[12]

The laminate according to any one of [8] to [11],
in which the resin layer has an elastic modulus of 1.2 GPa or more.

[13]

A method for producing the laminate according to any one of [8] to [12], the method comprising:
a step of attaching a composition for forming an adhesive layer, including a compound having a reactive group, onto a polymer film to obtain a polymer film with the adhesive layer, in which the adhesive layer is arranged on the polymer film; and
a step of arranging a metal foil on the adhesive layer in the polymer film with the adhesive layer, and thermocompression-bonding the adhesive layer and the metal foil to each other to form a metal layer on a resin layer obtained by curing the adhesive layer.

According to the present invention, it is possible to provide a polymer film with an adhesive layer, capable of forming a laminate, in which in a case where a metal foil is arranged on and compression-bonded to the adhesive layer, the adhesiveness of a metal layer formed from the metal foil is excellent and the dielectric loss tangent of a portion other than the metal layer is low.

In addition, according to the present invention, it is possible to provide a laminate obtained by using the polymer film with an adhesive layer and a method for producing the laminate.

### DESCRIPTION OF THE PREFERRED EMBODIMENTS

Hereinafter, the present invention will be described in detail.

Descriptions on the constitutional requirements which will be described later are made based on representative embodiments of the present invention in some cases, but it should not be construed that the present invention is limited to such embodiments.

In notations for a group (atomic group) in the present specification, in a case where the group is noted without specifying whether it is substituted or unsubstituted, the group includes both a group having no substituent and a group having a substituent as long as this does not impair the spirit of the present invention. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

In the present specification, in a case where the polymer film is in the form of a long film, a width direction of the polymer film means the lateral direction and the transverse direction (TD), and a length direction means the longitudinal direction and the machine direction (MD) of the polymer film.

In the present specification, for each component, one kind of substance corresponding to each component may be used alone, or two or more kinds thereof may be used in combination. Here, in a case where two or more kinds of substances are used for each component, the content of the component indicates a total content of two or more substances unless otherwise specified.

In the present specification, “to” is used in a meaning including numerical values denoted before and after “to” as a lower limit value and an upper limit value, respectively.

In the present specification, the dielectric loss tangent measured under the conditions of a temperature of 23° C. and a frequency of 28 GHz is also described as a “standard dielectric loss tangent”.

In the present specification, the “film width” means a distance between both ends of a long polymer film in the width direction.

In the present specification, the polymer film may be simply referred to as a “film”.

In the present specification, a (meth)acrylic acid is a generic term for an “acrylic acid” and a “methacrylic acid”.

[Polymer Film with Adhesive Layer]

A first embodiment of the polymer film with an adhesive layer of the present invention is a polymer film with an adhesive layer, including a polymer film including a polymer having a standard dielectric loss tangent of 0.005 or less, and the adhesive layer arranged on the polymer film. In addition, in a case where a surface of the polymer film on a side of the adhesive layer is measured by X-ray photoelectron spectroscopy, an atomic ratio of oxygen atoms to carbon atoms is 0.27 or more. Furthermore, the adhesive layer includes a compound having a reactive group. Moreover, the adhesive layer has a thickness of 1 μm or less. In addition, the adhesive layer has a post-curing elastic modulus of 0.8 GPa or more.

According to the first embodiment of the polymer film with an adhesive layer of the present invention, it is possible to form a laminate, in which in a case where a metal foil is arranged on and compression-bonded to the adhesive layer, the adhesiveness of a metal layer formed from the metal foil is excellent and the standard dielectric loss tangent of a portion other than the metal layer is low. Details of a reason thereof are not clear, but are usually presumed to be as follows.

In a case where the thickness of the adhesive layer in a polymer film with the adhesive layer is large, the adhesiveness of a metal layer contained in a laminate obtained by using the adhesive layer is improved, but even with use of a polymer film having a low standard dielectric loss tangent, the standard dielectric loss tangent of a dielectric constituting the laminate is increased. Furthermore, a dielectric constituting the laminate is a portion other than the metal layer constituting the laminate, and examples thereof include a cured resin layer of an adhesive layer and a polymer film.

On the other hand, in a case where the thickness of the adhesive layer in the polymer film with the adhesive layer is small, the standard dielectric loss tangent of a dielectric constituting the laminate can be lowered, but the adhesiveness of the metal layer of the laminate obtained by using the same is decreased.

As described above, there is a trade-off relationship between an improvement of the adhesiveness of the metal layer and a reduction in the standard dielectric loss tangent of a dielectric constituting the laminate.

With regard to the problem, the present inventors have found that even in a case where the adhesive layer has a reduced thickness, an atomic ratio of oxygen atoms to carbon atoms on a surface of the polymer film on a side of the adhesive layer (hereinafter also referred to as “an oxygen ratio on a surface of the polymer film”) is 0.27 or more, and in a case where the adhesive layer includes a compound having a reactive group and the adhesive layer has a post-curing elastic modulus of 0.8 GPa or more, it is possible to achieve both the improvement of the adhesiveness of the metal layer and the reduction in the standard dielectric loss tangent of a dielectric constituting the laminate.

It is considered that by setting the oxygen ratio on a surface of the polymer film to be equal to or higher than the above-described value, the group including an oxygen atom on the surface of the polymer film and the reactive group contained in the reactive compound in the adhesive layer sufficiently react with each other during a formation of the laminate, and thus, the adhesiveness between a resin layer (a layer obtained by curing the adhesive layer) and the polymer film is improved.

In addition, it is considered that by setting the post-curing elastic modulus of the adhesive layer to be equal to or higher than the value, a stress on a layer (resin layer) obtained by curing the adhesive layer is relaxed and a cohesive failure of the resin layer is suppressed.

It is presumed that these actions synergistically function to improve the adhesiveness of the metal layer even in a case where the adhesive layer has a reduced thickness.

[Polymer Film]

The polymer film includes a polymer having a standard dielectric loss tangent of 0.005 or less. The polymer having a standard dielectric loss tangent of 0.005 or less is not particularly limited, and examples thereof include a liquid crystal polymer, a polyphenylene sulfide, a syndiotactic polystyrene, a cyclic polyolefin, a fluororesin, and a polyimide. In the measurement of the dielectric loss tangent of the polymer in the present disclosure, the chemical structure of a polymer constituting each layer is specified or isolated, and the standard dielectric loss tangent of a sample obtained by using the polymer as a powder to be measured is measured according to a method for measuring a standard dielectric loss tangent described in the section of Examples which will be described later.

Hereinafter, the polymer film will be described in more detail by taking a liquid crystal polymer as an example.

<Liquid Crystal Polymer>

The polymer film preferably includes a liquid crystal polymer.

The liquid crystal polymer is preferably a thermotropic liquid crystal polymer. The thermotropic liquid crystal polymer means a polymer which exhibits liquid crystallinity in a predetermined temperature range.

The thermotropic liquid crystal polymer is not particularly limited in terms of the chemical composition as long as it is a melt-moldable liquid crystal polymer, and examples thereof include a thermoplastic liquid crystal polyester and a thermoplastic polyester amide with an amide bond introduced into the thermoplastic liquid crystal polyester.

As the liquid crystal polymer, for example, the thermoplastic liquid crystal polymer described in WO2015/064437A and JP2019-116586A can be used.

Specific preferred examples of the liquid crystal polymer include a thermoplastic liquid crystal polyester or thermoplastic liquid crystal polyester amide having a repeating unit derived from at least one selected from the group consisting of an aromatic hydroxycarboxylic acid, an aromatic or aliphatic diol, an aromatic or aliphatic dicarboxylic acid, an aromatic diamine, an aromatic hydroxyamine, and an aromatic aminocarboxylic acid.

Examples of the aromatic hydroxycarboxylic acid include parahydroxybenzoic acid, metahydroxybenzoic acid, 6-hydroxy-2-naphthoic acid, and 4-(4-hydroxyphenyl)benzoic acid. These compounds may have substituents such as a halogen atom, a lower alkyl group, and a phenyl group. Among these, the parahydroxybenzoic acid or the 6-hydroxy-2-naphthoic acid is preferable.

As the aromatic or aliphatic diol, the aromatic diol is preferable. Examples of the aromatic diol include hydroquinone, 4,4′-dihydroxybiphenyl, 3,3′-dimethyl-1,1′-biphenyl-4,4′-diol, and acylated products thereof, and hydroquinone or 4,4′-dihydroxybiphenyl is preferable.

As the aromatic or aliphatic dicarboxylic acid, the aromatic dicarboxylic acid is preferable. Examples of the aromatic dicarboxylic acid include terephthalic acid, isophthalic acid, and 2,6-naphthalenedicarboxylic acid, and terephthalic acid is preferable.

Examples of the aromatic diamine, the aromatic hydroxyamine, and the aromatic aminocarboxylic acid include p-phenylenediamine, 4-aminophenol, and 4-aminobenzoic acid.

The liquid crystal polymer preferably has at least one selected from the group consisting of a repeating unit derived from an aromatic hydroxycarboxylic acid, a repeating unit derived from an aromatic diol, and a repeating unit derived from an aromatic dicarboxylic acid.

Among those, the liquid crystal polymer more preferably has at least the repeating unit derived from an aromatic hydroxycarboxylic acid, still more preferably has at least one selected from the group consisting of a repeating unit derived from parahydroxybenzoic acid and a repeating unit derived from 6-hydroxy-2-naphthoic acid, and particularly preferably has the repeating unit derived from parahydroxybenzoic acid and the repeating unit derived from 6-hydroxy-2-naphthoic acid.

In addition, in another preferred aspect, the liquid crystal polymer preferably has at least one selected from the group consisting of the repeating unit derived from 6-hydroxy-2-naphthoic acid, the repeating unit derived from an aromatic diol, a repeating unit derived from terephthalic acid, and a repeating unit derived from a 2,6-naphthalenedicarboxylic acid, and more preferably has all of the repeating unit derived from 6-hydroxy-2-naphthoic acid, the repeating unit derived from an aromatic diol, the repeating unit derived from terephthalic acid, and the repeating unit derived from 2,6-naphthalenedicarboxylic acid.

In a case where the liquid crystal polymer includes the repeating unit derived from an aromatic hydroxycarboxylic acid, a compositional ratio of the repeating unit is preferably 50% to 65% by mole with respect to all the repeating units of the liquid crystal polymer. In addition, it is also preferable that the liquid crystal polymer has only the repeating unit derived from an aromatic hydroxycarboxylic acid.

In a case where the liquid crystal polymer includes the repeating unit derived from an aromatic diol, a compositional ratio of the repeating unit is preferably 17.5% to 25% by mole with respect to all the repeating units of the liquid crystal polymer.

In a case where the liquid crystal polymer includes the repeating unit derived from an aromatic dicarboxylic acid, a compositional ratio of the repeating unit is preferably 11% to 23% by mole with respect to all the repeating units of the liquid crystal polymer.

In a case where the liquid crystal polymer includes the repeating unit derived from any of an aromatic diamine, an aromatic hydroxyamine, and an aromatic aminocarboxylic acid, a compositional ratio of the repeating unit is preferably 2% to 8% by mole with respect to all the repeating units of the liquid crystal polymer.

A method for synthesizing the liquid crystal polymer is not particularly limited, and the compound can be synthesized by polymerizing the compound by a known method such as melt polymerization, solid phase polymerization, solution polymerization, and slurry polymerization.

As the liquid crystal polymer, a commercially available product may be used. Examples of the commercially available product of the liquid crystal polymer include “LAPEROS” manufactured by Polyplastics Co., Ltd., “VECTRA” manufactured by Celanese Corporation, “UENO LCP” manufactured by Ueno Fine Chemicals Industry, Ltd., “SUMIKA SUPER LCP” manufactured by Sumitomo Chemical Co., Ltd., “XYDAR” manufactured by ENEOS LC Co., Ltd., and “SIVERAS” manufactured by Toray Industries, Inc.

Furthermore, the liquid crystal polymer may form a chemical bond in the polymer film with a crosslinking agent, a compatible component (reactive compatibilizer), or the like which is an optional component. The same applies to components other than the liquid crystal polymer.

The standard dielectric loss tangent of the liquid crystal polymer is 0.005 or less, and from the viewpoint that a laminate having a low standard dielectric loss tangent of a portion other than the metal layer can be obtained and a communication circuit board having a smaller transmission loss can be manufactured, the standard dielectric loss tangent is preferably 0.003 or less, more preferably 0.0025 or less, and still more preferably 0.002 or less.

The lower limit value is not particularly limited, and may be, for example, 0.0001 or more.

In the present specification, in a case where the polymer film includes two or more kinds of liquid crystal polymers, the “dielectric loss tangent of the liquid crystal polymer” means a mass-average value of the dielectric loss tangents of two or more kinds of liquid crystal polymers.

The dielectric loss tangent of the liquid crystal polymer included in the polymer film can be measured by the following method.

First, after performing immersion in an organic solvent (for example, pentafluorophenol) in an amount of 1,000 times by mass with respect to the total mass of the polymer film, the mixture is heated at 120° C. for 12 hours to elute the organic solvent-soluble components including the liquid crystal polymer into the organic solvent. Next, the eluate including the liquid crystal polymer and the non-eluted components are separated by filtration. Subsequently, acetone is added to the eluate as a poor solvent to precipitate a liquid crystal polymer, and the precipitate is separated by filtration.

A dielectric loss tangent of the liquid crystal polymer can be obtained by filling a polytetrafluoroethylene (PTFE) tube (outer diameter: 2.5 mm, inner diameter: 1.5 mm, length: 10 mm) with the obtained precipitate, measuring the dielectric characteristics by a cavity resonator perturbation method under the conditions of a temperature of 23° C., a humidity of 50% RH, and a frequency of 28 GHz, using a cavity resonator (for example, “CP-531” manufactured by Kanto Electronics Application & Development, Inc.), and correcting the influence of voids in the PTFE tube by a Bruggeman formula and a void ratio.

The void ratio (volume fraction of the void in the tube) is calculated as follows. The volume of a space inside the tube is determined from the inner diameter and the length of the tube. Next, the weights of the tube before and after filling the precipitate are measured to determine the mass of the filled precipitate, and then the volume of the filled precipitate is determined from the obtained mass and the specific gravity of the precipitate. The void ratio can be calculated by dividing the volume of the precipitate thus obtained by the volume of the space in the tube determined above to calculate a filling rate.

Furthermore, in a case where a commercially available product of the liquid crystal polymer is used, a numerical value of the dielectric loss tangent described as a catalog value of the commercially available product may be used.

As for the liquid crystal polymer, the melting point Tm is preferably 270° C. or higher, more preferably 285° C. or higher, and still more preferably 300° C. or higher from the viewpoint that the effect of the present invention is more excellent.

The upper limit value of the melting point Tm of the liquid crystal polymer is not particularly limited, but is preferably 400° C. or lower, and more preferably 380° C. or lower.

The melting point Tm of the liquid crystal polymer can be determined by measuring a temperature at which the endothermic peak appears, using a differential scanning calorimeter (“DSC-60A” manufactured by Shimadzu Corporation). In a case where a commercially available product of the liquid crystal polymer is used, the melting point Tm described as the catalog value of the commercially available product may be used.

The liquid crystal polymers may be used alone or in combination of two or more kinds thereof.

The content of the liquid crystal polymer is preferably 40% to 99.9% by mass, more preferably 60% to 99% by mass, and still more preferably 80% to 90% by mass with respect to the total mass of the polymer film.

<Optional Components>

The polymer film may include an additive other than the liquid crystal polymer as an optional component. Examples of the additive include a polyolefin, a compatible component, a heat stabilizer, a crosslinking agent, and a lubricant.

<Polyolefin>

In the present specification, the polyolefin is intended to be a resin having a repeating unit based on an olefin (a polyolefin resin).

The polymer film preferably further includes a polyolefin, and more preferably further includes a polyolefin and a compatible component, in addition to the liquid crystal polymer.

By producing a polymer film including a polyolefin together with the liquid crystal polymer, a polymer film having a disperse phase formed of the polyolefin can be produced. A method for producing the polymer film having a disperse phase will be described later.

The polyolefin may be linear or branched. In addition, the polyolefin may have a cyclic structure such as a polycycloolefin.

Examples of the polyolefin include polyethylene, polypropylene (PP), polymethylpentene (TPX and the like manufactured by Mitsui Chemicals, Inc.), hydrogenated polybutadiene, a cycloolefin polymer (COP, ZEONOR manufactured by ZEON Corporation, and the like), and a cycloolefin copolymer (COC, APEL manufactured by Mitsui Chemicals, Inc., and the like).

The polyethylene may be either high density polyethylene (HDPE) or low density polyethylene (LDPE). In addition, the polyethylene may be linear low density polyethylene (LLDPE).

The polyolefin may be a copolymer of an olefin and a copolymerization component other than the olefin, such as acrylate, methacrylate, styrene, and/or a vinyl acetate-based monomer.

Examples of the polyolefin as the copolymer include a styrene-ethylene/butylene-styrene copolymer (SEBS). SEBS may be hydrogenated.

However, from the viewpoint that the effect of the present invention is more excellent, it is preferable that a copolymerization ratio of the copolymerization component other than the olefin is small, and it is more preferable that the copolymerization component is not included. For example, a content of the copolymerization component is preferably 0% to 40% by mass, and more preferably 0% to 5% by mass with respect to the total mass of the polyolefin.

In addition, the polyolefin is preferably substantially free of a reactive group which will be described below, and a content of the repeating unit having the reactive group is preferably 0% to 3% by mass with respect to the total mass of the polyolefin.

As the polyolefin, polyethylene, COP, or COC is preferable, polyethylene is more preferable, and the low-density polyethylene (LDPE) is still more preferable from the viewpoint that the effect of the present invention is more excellent.

The polyolefins may be used alone or in combination of two or more kinds thereof.

The content of the polyolefin is preferably 0.1% by mass or more, and more preferably 5% by mass or more with respect to the total mass of the polymer film from the viewpoint that the surface properties of the polymer film are more excellent.

The upper limit of the content is preferably 50% by mass or less, more preferably 40% by mass or less, and still more preferably 25% by mass or less from the viewpoint that the smoothness of the polymer film is more excellent. In addition, in a case where the content of the polyolefin is set to 50% by mass or less, the thermal deformation temperature can be easily raised sufficiently and the solder heat resistance can be improved.

(Compatible Component)

Examples of the compatible component include a polymer (non-reactive compatibilizer) having a moiety having high compatibility or affinity with the liquid crystal polymer and a polymer (reactive compatibilizer) having a reactive group for a phenol-based hydroxyl group or a carboxy group at the terminal of the liquid crystal polymer.

As the reactive group included in the reactive compatibilizer, an epoxy group or a maleic acid anhydride group is preferable.

As the compatible component, a copolymer having a moiety having a high compatibility or a high affinity with the polyolefin is preferable. In addition, in a case where the polymer film includes a polyolefin and a compatible component, a reactive compatibilizer is preferable as the compatible component from the viewpoint that the polyolefin can be finely dispersed.

Furthermore, the compatible component (in particular, the reactive compatibilizer) may form a chemical bond with a component such as a liquid crystal polymer in the polymer film.

Examples of the reactive compatibilizer include an epoxy group-containing polyolefin-based copolymer, an epoxy group-containing vinyl-based copolymer, a maleic acid anhydride-containing polyolefin-based copolymer, a maleic acid anhydride-containing vinyl copolymer, an oxazoline group-containing polyolefin-based copolymer, an oxazoline group-containing vinyl-based copolymer, and a carboxy group-containing olefin-based copolymer. Among these, the epoxy group-containing polyolefin-based copolymer or the maleic acid anhydride-grafted polyolefin-based copolymer is preferable.

Examples of the epoxy group-containing polyolefin-based copolymer include an ethylene/glycidyl methacrylate copolymer, an ethylene/glycidyl methacrylate/vinyl acetate copolymer, an ethylene/glycidyl methacrylate/methyl acrylate copolymer, a polystyrene graft copolymer to an ethylene/glycidyl methacrylate copolymer (EGMA-g-PS), a polymethylmethacrylate graft copolymer to an ethylene/glycidyl methacrylate copolymer (EGMA-g-PMMA), and an acrylonitrile/styrene graft copolymer to an ethylene/glycidyl methacrylate copolymer (EGMA-g-AS).

Examples of a commercially available product of the epoxy group-containing polyolefin-based copolymer include BONDFIRST 2C and BONDFIRST E manufactured by Sumitomo Chemical Co., Ltd.; Lotadar manufactured by Arkema S.A.; and MODIPER A4100 and MODIPER A4400 manufactured by NOF Corporation.

Examples of the epoxy group-containing vinyl-based copolymer include a glycidyl methacrylate grafted polystyrene (PS-g-GMA), a glycidyl methacrylate grafted polymethyl methacrylate (PMMA-g-GMA), and a glycidyl methacrylate grafted polyacrylonitrile (PAN-g-GMA).

Examples of the maleic acid anhydride-containing polyolefin-based copolymer include a maleic acid anhydride grafted polypropylene (PP-g-MAH), a maleic acid anhydride grafted ethylene/propylene rubber (EPR-g-MAH), and a maleic acid anhydride grafted ethylene/propylene/diene rubber (EPDM-g-MAH).

Examples of a commercially available product of the maleic acid anhydride-containing polyolefin-based copolymer include Orevac G series manufactured by Arkema S. A.; and FUSABOND E series manufactured by The Dow Chemical Company.

Examples of the maleic acid anhydride-containing vinyl copolymer include a maleic acid anhydride grafted polystyrene (PS-g-MAH), a maleic acid anhydride grafted styrene/butadiene/styrene copolymer (SBS-g-MAH), a maleic acid anhydride grafted styrene/ethylene/butene/styrene copolymer (SEBS-g-MAH and a styrene/maleic acid anhydride copolymer, and an acrylic acid ester/maleic acid anhydride copolymer.

Examples of a commercially available product of the maleic acid anhydride-containing vinyl copolymer include TUFTEC M Series (SEBS-g-MAH) manufactured by Asahi Kasei Corporation.

In addition to those, examples of the compatible component include oxazoline-based compatibilizers (for example, a bisoxazoline-styrene-maleic acid anhydride copolymer, a bisoxazoline-maleic acid anhydride-modified polyethylene, and a bisoxazoline-maleic acid anhydride-modified polypropylene), elastomer-based compatibilizers (for example, an aromatic resin and a petroleum resin), ethylene glycidyl methacrylate copolymer, an ethylene maleic acid anhydride ethyl acrylate copolymer, ethylene glycidyl methacrylate-acrylonitrile styrene, acid-modified polyethylene wax, a COOH-modified polyethylene graft polymer, a COOH-modified polypropylene graft polymer, a polyethylene-polyamide graft copolymer, a polypropylene-polyamide graft copolymer, a methyl methacrylate-butadiene-styrene copolymer, acrylonitrile-butadiene rubber, an EVA-PVC-graft copolymer, a vinyl acetate-ethylene copolymer, an ethylene-α-olefin copolymer, a propylene-α-olefin copolymer, a hydrogenated styrene-isopropylene-block copolymer, and an amine-modified styrene-ethylene-butene-styrene copolymer.

In addition, as the compatible component, an ionomer resin may be used.

Examples of such an ionomer resin include an ethylene-methacrylic acid copolymer ionomer, an ethylene-acrylic acid copolymer ionomer, a propylene-methacrylic acid copolymer ionomer, a butylene-acrylic acid copolymer ionomer, a propylene-acrylic acid copolymer ionomer, an ethylene-vinyl sulfonic acid copolymer ionomer, a styrene-methacrylic acid copolymer ionomer, a sulfonated polystyrene ionomer, a fluorine-based ionomer, a telechelic polybutadiene acrylic acid ionomer, a sulfonated ethylene-propylene-diene copolymer ionomer, hydrogenated polypentamer ionomer, a polypentamer ionomer, a poly(vinylpyridium salt) ionomer, a poly(vinyltrimethylammonium salt) ionomer, a poly(vinyl benzyl phosphonium salt) ionomer, a styrene-butadiene acrylic acid copolymer ionomer, a polyurethane ionomer, a sulfonated styrene-2-acrylamide-2-methyl propane sulfate ionomer, an acid-amine Ionomer, an aliphatic ionene, and an aromatic ionene.

In a case where the polymer film includes the compatible component, a content thereof is preferably 0.05% to 30% by mass, more preferably 0.1% to 20% by mass, and still more preferably 0.5% to 10% by mass with respect to the total mass of the polymer film.

(Heat Stabilizer)

Examples of the heat stabilizer include a phenol-based stabilizer and an amine-based stabilizer, each having a radical scavenging action; a phosphite-based stabilizer and a sulfur-based stabilizer, each having a decomposition action of a peroxide; and a hybrid stabilizer having a radical scavenging action and a decomposition action of a peroxide.

The polymer film preferably includes a heat stabilizer, and more preferably includes the heat stabilizer together with the liquid crystal polymer, the polyolefin, and the compatible component. By allowing the polymer film to include the heat stabilizer, the deterioration of thermal oxidation during a melt extrusion film formation is suppressed, and the surface properties and the smoothness of a surface of the polymer film are improved.

Examples of the phenol-based stabilizer include a hindered phenol-based stabilizer, a semi-hindered phenol-based stabilizer, and a less hindered phenol-based stabilizer.

Examples of a commercially available product of the hindered phenol-based stabilizer include ADK STAB AO-20, AO-50, AO-60, and AO-330 manufactured by ADEKA Corporation; and Irganox 259, 1035, and 1098 manufactured by BASF.

Examples of a commercially available product of the semi-hindered phenol-based stabilizer include ADK STAB AO-80 manufactured by ADEKA Corporation; and Irganox 245 manufactured by BASF.

Examples of a commercially available product of the less hindered phenol-based stabilizer include NOCRAC 300 manufactured by Ouchi Shinko Chemical Industrial Co., Ltd.; and ADK STAB AO-30 and AO-40 manufactured by ADEKA Corporation.

Examples of a commercially available product of the phosphite-based stabilizer include ADK STAB-2112, PEP-8, PEP-36, and HP-10 manufactured by ADEKA Corporation.

Examples of a commercially available product of the hybrid stabilizer include SUMILIZER GP manufactured by Sumitomo Chemical Co., Ltd.

The heat stabilizers may be used alone or in combination of two or more kinds thereof.

In a case where the polymer film includes the heat stabilizer, a content thereof is preferably 0.0001% to 10% by mass, more preferably 0.001% to 5% by mass, and still more preferably 0.01% to 2% by mass with respect to the total mass of the polymer film.

(Crosslinking Agent)

The crosslinking agent is a low-molecular-weight compound having two or more reactive groups. The reactive group is a functional group capable of reacting with a phenolic hydroxyl group or a carboxy group at a terminal of the liquid crystal polymer.

Examples of the reactive group include an epoxy group, a maleic acid anhydride group, an oxazoline group, an isocyanate group, and a carbodiimide group.

Examples of the crosslinking agent include a bisphenol A type epoxy compound, a bisphenol F type epoxy compound, a phenol novolac type epoxy compound, a cresol novolac type epoxy compound, and a diisocyanate compound.

The crosslinking agents may be used alone or in combination of two or more kinds thereof. The content of the crosslinking agent is preferably 0% to 10% by mass, and more preferably 0% to 5% by mass with respect to the total mass of the polymer film.

(Other Additives)

The polymer film may include other additives.

Examples of such other additives include a plasticizer, a lubricant, inorganic and organic particles, and a UV absorbing material.

Examples of the plasticizer include an alkylphthalyl alkyl glycolate compound, a bisphenol compound (bisphenol A, bisphenol F), a phosphoric acid ester compound, a carboxylic acid ester compound, and a polyhydric alcohol. The content of the plasticizer may be 0% to 5% by mass with respect to the total mass of the polymer film.

Examples of the lubricant include a fatty acid ester and a metal soap (for example, a stearic acid inorganic salt). The content of the lubricant may be 0% to 5% by mass with respect to the total mass of the polymer film.

The polymer film may contain inorganic particles and/or organic particles as a reinforcing material, a matting agent, a dielectric constant, or a dielectric loss tangent improving material. Examples of inorganic particles include silica, titanium oxide, barium sulfate, talc, zirconia, alumina, silicon nitride, silicon carbide, calcium carbonate, silicate, glass beads, graphite, tungsten carbide, carbon black, clay, mica, carbon fiber, glass fiber, and metal powder. Examples of the organic particles include crosslinked acryl and crosslinked styrene. The content of the inorganic particles and the organic particles may be 0% to 50% by mass with respect to the total mass of the polymer film.

Examples of the UV absorbing material include a salicylate compound, a benzophenone compound, a benzotriazole compound, a substituted acrylonitrile compound, and an s-triazine compound. The content of the UV absorbing material may be 0% to 5% by mass with respect to the total mass of the polymer film.

<Physical Properties of Polymer Film>

(Dielectric Characteristics)

The polymer film has an excellent standard dielectric loss tangent. Specifically, the standard dielectric loss tangent of the polymer film is preferably 0.005 or less, more preferably 0.0025 or less, still more preferably 0.002 or less, and particularly preferably 0.0015 or less. The lower limit value is not particularly limited, and may be 0.0001 or more.

In addition, a relative permittivity of the polymer film varies depending on the application, but is preferably 2.0 to 4.0, and more preferably 2.5 to 3.5.

The dielectric characteristics including a dielectric loss tangent and a relative permittivity of the polymer film can be measured by a cavity resonator perturbation method. A specific method for measuring the dielectric characteristics of the polymer film will be described in the section of Examples which will be described later.

(Thickness)

The thickness of the polymer film is preferably 5 to 1,000 μm, more preferably 10 to 500 μm, and still more preferably 20 to 300 μm.

(Surface Roughness)

The surface roughness Ra of the polymer film is preferably less than 430 nm, more preferably less than 400 nm, particularly preferably less than 350 nm, and still more preferably less than 300 nm.

The lower limit value of the surface roughness Ra of the polymer film is not particularly limited and is, for example, 10 nm or more.

It is considered that in a case where the surface roughness Ra of the polymer film is within the range, the dimensional change occurring in the polymer film is easily absorbed, and more excellent surface properties and smoothness can be realized.

The surface roughness Ra of the polymer film is determined by arithmetically averaging measured values obtained by a measurement using a stylus type roughness meter according to JIS B 0601 at five randomly selected positions within a region of 10 cm×10 cm in the center portion of the polymer film.

(Disperse Phase)

In a case where the polymer film includes a polyolefin, it is preferable that the polyolefin forms a disperse phase in the polymer film.

The disperse phase corresponds to an island portion in a polymer film that forms a so-called sea-island structure.

A method for allowing the polyolefin to exist as a disperse phase by forming a sea-island structure in the polymer film is not limited, and for example, a disperse phase of a polyolefin can be formed by adjusting each of the contents of the liquid crystal polymer and the polyolefin in the polymer film to the above-mentioned suitable contents.

An average disperse diameter of the disperse phase is preferably 0.001 to 50.0 μm, more preferably 0.005 to 20.0 μm, and still more preferably 0.01 to 10.0 μm from the viewpoint that the smoothness in the polymer film is more excellent.

A method for measuring the average dispersion diameter will be described in the section of Examples which will be described later.

The disperse phase is preferably flat, and a smooth surface of the flat disperse phase is preferably substantially parallel to the polymer film.

In addition, from the viewpoint of reducing the anisotropy of the polymer film, the smooth surface of the flat disperse phase is preferably substantially circular in a case of being observed from a direction perpendicular to the surface of the polymer film. It is considered that in a case where such a disperse phase is dispersed in the polymer film, a dimensional change which occurs in the polymer film can be absorbed, and more excellent surface properties and smoothness can be realized.

(Oxygen Ratio on Surface of Polymer Film)

The oxygen ratio on a surface of the polymer film is 0.27 or more. As described above, the “oxygen ratio on a surface of the polymer film” means an atomic ratio (oxygen atoms/oxygen atoms) of oxygen atoms to carbon atoms in a case where the surface of the polymer film on a side of the adhesive layer is measured by X-ray photoelectron spectroscopy).

The oxygen ratio on the surface of the polymer film is preferably 0.28 or more, and more preferably 0.30 or more from the viewpoint that the adhesiveness of the metal layer is more excellent.

The oxygen ratio on the surface of the polymer film is preferably 0.90 or less, more preferably 0.70 or less, and still more preferably 0.50 or less from the viewpoint of the low dielectric loss tangent.

The oxygen ratio on the surface of the polymer film is measured by X-ray photoelectron spectroscopy, and a specific measurement method therefor will be described in the section of Examples which will be described later.

The method for setting the oxygen ratio of the surface of the polymer film within the above-described range is not particularly limited, and examples thereof include a method of subjecting the polymer film to a surface treatment (a corona treatment, a plasma treatment, and the like) which will be described later.

<Method for Producing Polymer Film>

A method for producing a polymer film is not particularly limited, but preferably includes a pelletizing step of kneading each of the above-mentioned components to obtain pellets, and a film producing step of obtaining a liquid crystal polymer film using the pellets. The steps will be described below.

(Pelletizing Step)

(1) Forms of Raw Material

As the liquid crystal polymer used for film production, a pellet-shaped, flake-shaped, or powdered polymer can be used as it is, but for the purpose of stabilizing the film production or uniformly dispersing additives (which means components other than the liquid crystal polymer; the same applies hereinafter), it is preferable to use pellets obtained by kneading one or more kinds of raw materials (meaning at least one of a liquid crystal polymer or an additive; the same applies hereinafter) using an extruder, followed by pelletizing.

Hereinafter, a mixture including a raw material which is a polymer, and a polymer used for producing a polymer film is also collectively referred to as a resin.

(2) Drying or Drying Alternative by Vent

Before pelletizing, it is preferable to dry the liquid crystal polymer and the additive in advance. Examples of the drying method include a method of circulating heated air having a low dew point, and a method of dehumidifying by vacuum drying. In particular, in a case of a resin which is easily oxidized, vacuum drying or drying using an inert gas is preferable.

(3) Method for Supplying Raw Materials

A method for supplying raw materials may be a method in which raw materials are mixed in advance before being kneaded and pelletized, and then supplied, a method in which raw materials are separately supplied into the extruder so as to be in a fixed ratio, or a method of a combination of the both.

(4) Atmosphere During Extrusion

In a case of melt extrusion, within a range not interfering with uniform dispersion, it is preferable to prevent thermal and oxidative deterioration as much as possible, and it is also effective to reduce an oxygen concentration by reducing the pressure using a vacuum pump or inflowing an inert gas. These methods may be carried out alone or in combination.

(5) Temperature

A kneading temperature is preferably set to be equal to or lower than a thermal decomposition temperature of the liquid crystal polymer and the additive, and is preferably set to a low temperature as much as possible within a range in which a load of the extruder and a decrease in uniform kneading property are not a problem.

(6) Pressure

A kneading resin pressure during pelletization is preferably 0.05 to 30 MPa. In a case of a resin in which coloration or gel is likely to be generated due to shearing, it is preferable to apply an internal pressure of approximately 1 to 10 MPa to the inside of the extruder to fill the inside of a twin-screw extruder with the resin raw material.

(7) Pelletizing Method

As a pelletizing method, a method of solidifying a noodle-shaped extrusion in water and then cutting the extrusion is generally used, but the pelletization may be performed by an under-water cut method for cutting while directly extruding from a mouthpiece into water after melting with the extruder, or a hot cut method for cutting while still hot.

(8) Pellet Size

A pellet size is preferably 1 to 300 mm² in a cross-sectional area and 1 to 30 mm in a length, and more preferably 2 to 100 mm² in a cross-sectional area and 1.5 to 10 mm in a length.

(Drying)

(1) Purpose of Drying

Before the molten film production, it is preferable to reduce a moisture and a volatile fraction in the pellets, and it is effective to dry the pellets. In a case where the pellets include a moisture or a volatile fraction, not only appearance is deteriorated due to incorporation of bubbles into a film to be produced or the decrease in a haze, but also physical properties may be deteriorated due to a molecular chain breakage of the liquid crystal polymer, or roll contamination may occur due to generation of monomers or oligomers. In addition, depending on the type of the liquid crystal polymer used, it may be possible to suppress generation of an oxidative crosslinked substance during the molten film production by removing dissolved oxygen by the drying.

(2) Drying Method and Heating Method

From the viewpoints of a drying efficiency and an economical efficiency, a dehumidifying hot air dryer is generally used as a drying method, but the drying method is not particularly limited as long as a desired moisture content can be obtained. In addition, there is no problem in selecting a more appropriate method according to characteristics of the physical properties of the liquid crystal polymer.

Examples of a heating method include pressurized steam, heater heating, far-infrared irradiation, microwave heating, and a heat medium circulation heating method.

(Film Producing Step)

Hereinafter, the film producing step will be described.

(1) Extrusion Conditions

Drying of Raw Materials

In a melt plasticization step for pellets using an extruder, it is preferable to reduce a moisture and a volatile fraction in the pellets as in the pelletizing step, and it is effective to dry the pellets.

Method for Supplying Raw Materials

In a case where there are multiple types of raw materials (pellets) input from the extruder supply port, the raw materials may be mixed in advance (premix method), may be separately supplied into the extruder in a fixed ratio, or may be a combination of the both. In addition, in order to stabilize the extrusion, it is generally practiced to reduce a fluctuation of the temperature and a bulk specific gravity of the raw material charged from the supply port. Moreover, from the viewpoint of a plasticization efficiency, a raw material temperature is preferably high as long as it does not block a supply port by pressure-sensitive adherence, and in a case where the raw material is in an amorphous state, the raw material temperature is preferably in the range of {Glass transition temperature (Tg) (° C.)−150° C.} to {Tg (° C.)−1° C.}, and in a case where the raw material is a crystalline resin, the raw material temperature is preferably in the range of {Melting point (Tm) (° C.)−150° C.} to {Tm (° C.)−1° C.}, and the raw material is heated or kept warm. In addition, from the viewpoint of the plasticization efficiency, the bulk specific gravity of the raw material is preferably 0.3 times or more, and more preferably 0.4 times or more in a case of a molten state. In a case where the bulk specific gravity of the raw material is less than 0.3 times the specific gravity in the molten state, it is also preferable to perform a processing treatment such as compression of the raw material into pseudo-pellets.

Atmosphere During Extrusion

As for the atmosphere during melt extrusion, it is necessary to prevent heat and oxidative deterioration as much as possible within a range that does not hinder uniform dispersion as in the pelletizing step. It is also effective to inject an inert gas (nitrogen or the like), reduce the oxygen concentration in the extruder by using a vacuum hopper, and provide a vent port in the extruder to reduce the pressure by a vacuum pump. These depressurization and injection of the inert gas may be carried out independently or in combination.

Rotation Speed

A rotation speed of the extruder is preferably 5 to 300 rpm, more preferably 10 to 200 rpm, and still more preferably 15 to 100 rpm. In a case where the rotation rate is set to the lower limit value or more, the retention time is shortened, the decrease in the molecular weight can be suppressed due to thermal deterioration, and discoloration can be suppressed. In a case where the rotation rate is set to the upper limit value or less, a breakage of a molecular chain due to shearing can be suppressed, and a decrease in the molecular weight and an increase in generation of crosslinked gel can be suppressed. It is preferable to select appropriate conditions for the rotation speed from the viewpoints of both uniform dispersibility and thermal deterioration due to extension of the retention time.

Temperature

A barrel temperature (a supply unit temperature of T₁° C., a compression unit temperature of T₂° C., and a measuring unit temperature of T₃° C.) is generally determined by the following method. In a case where the pellets are melt-plasticized at a target temperature T° C. by the extruder, the measuring unit temperature T₃ is set to T±20° C. in consideration of the shear calorific value. At this time, T₂ is set within a range of T₃±20° C. in consideration of extrusion stability and thermal decomposability of the resin. Generally, T₁ is set to {T₂ (° C.)−5° C.} to {T₂ (° C.)−150° C.}, and the optimum value of T₁ is selected from the viewpoint of ensuring a friction between the resin and the barrel, which is a driving force (feed force) for feeding the resin, and preheating at the feed unit. In a case of a normal extruder, it is possible to subdivide each zone of T₁ to T₃ and set the temperature, and by performing settings such that the temperature change between each zone is gentle, it is possible to make it more stable. At this time, T is preferably set to be equal to or lower than the thermal deterioration temperature of the resin, and in a case where it exceeds the thermal deterioration temperature due to the shear heat generation of the extruder, it is generally performed to positively cool and remove the shear heat generation. In addition, in order to achieve both improved dispersibility and thermal deterioration, it is also effective to melt and mix a first half part in the extruder at a relatively high temperature and lower the resin temperature in a second half part.

Pressure

A resin pressure in the extruder is generally 1 to 50 MPa, and from the viewpoints of extrusion stability and melt uniformity, the resin pressure is preferably 2 to 30 MPa, and more preferably 3 to 20 MPa. In a case where the pressure in the extruder is 1 MPa or more, a filling rate of the melting in the extruder is sufficient, and therefore, the destabilization of the extrusion pressure and the generation of foreign matter due to the generation of retention portions can be suppressed. In addition, in a case where the pressure in the extruder is 50 MPa or less, it is possible to suppress the excessive shear stress received in the extruder, and therefore, thermal decomposition due to an increase in the resin temperature can be suppressed.

Retention Time

A retention time in the extruder (retention time during the film production) can be calculated from a volume of the extruder portion and a discharge capacity of the polymer, as in the pelletizing step. The retention time is preferably 10 seconds to 60 minutes, more preferably 15 seconds to 45 minutes, and still more preferably 30 seconds to 30 minutes. In a case where the retention time is 10 seconds or more, the melt plasticization and the dispersion of the additive are sufficient. In a case where the retention time is 30 minutes or less, it is preferable from the viewpoint that resin deterioration and discoloration of the resin can be suppressed.

(Filtration)

Type, Purpose of Installation, and Structure

It is generally used to provide a filtration equipment at the outlet of the extruder in order to prevent damage to the gear pump due to foreign matter included in the raw material and to extend the life of the filter having a fine pore size installed downstream of the extruder. It is preferable to perform so-called breaker plate type filtration in which a mesh-shaped filtering medium is used in combination with a reinforcing plate having a high opening ratio and having strength.

Mesh Size and Filtration Area

A mesh size is preferably 40 to 800 mesh, more preferably 60 to 700 mesh, and still more preferably 100 to 600 mesh. In a case where the mesh size is 40 mesh or more, it is possible to sufficiently suppress foreign matter from passing through the mesh. In addition, in a case where the mesh is 800 mesh or less, the improvement of the filtration pressure increase speed can be suppressed and the mesh replacement frequency can be reduced. In addition, from the viewpoints of a filtration accuracy and a strength maintenance, a plurality of types of filter meshes having different mesh sizes are generally superimposed and used. Moreover, since the filtration opening area can be widened and the strength of the mesh can be maintained, reinforcement of a filter mesh using a breaker plate is also used. The opening ratio of the breaker plate to be used is generally 30% to 80% from the viewpoints of a filtration efficiency and a strength.

In addition, a screen changer with the same diameter as the barrel diameter of the extruder is often used, but in order to increase the filtration area, a larger diameter filter mesh is used by using a tapered pipe, or a plurality of breaker plates is also generally used by branching a flow channel. The filtration area is preferably selected with a flow rate of 0.05 to 5 g/cm² per second as a guide, more preferably 0.1 to 3 g/cm², and still more preferably 0.2 to 2 g/cm².

By capturing foreign matter, the filter is clogged and the filter pressure rises. At that time, it is necessary to stop the extruder and replace the filter, but a type in which the filter can be replaced while continuing extrusion can also be used. In addition, as a measure against an increase in the filtration pressure due to the capture of foreign matter, a measure having a function of lowering the filtration pressure by washing and removing the foreign matter trapped in the filter by reversing the flow channel of the polymer can also be used.

(Die)

Type, Structure, and Material

A molten resin from which foreign matters have been removed by filtration and in which the temperature has been made uniform by a mixer is continuously sent to the die. Any type of a T die, a fishtail die, or a hanger coat die, commonly used, can also be used as long as the die is designed so that the retention of the molten resin is small. Among these, the hanger coat die is preferable from the viewpoints of thickness uniformity and less retention.

Multilayer Film Production

A monolayer film producing device having a low equipment cost is generally used for the production of a film. In addition, a multilayer film producing device may be used in order to provide a functional layer such as a surface protective layer, a pressure-sensitive adhesive layer, an easy adhesion layer, and/or an antistatic layer in an outer layer. Specific examples thereof include a method of performing multilayering using a multilayer feed block and a method of using a multi-manifold die. It is generally preferable to laminate the functional layer thinly on the surface layer, but the layer ratio is not particularly limited.

(Cast)

The film producing step preferably includes a step of supplying a liquid crystal polymer in a molten state from the supply unit, and a step of landing the liquid crystal polymer in the molten state on a cast roll to form a film. The molten liquid crystal polymer may be cooled and solidified, and wound as it is as the film, or it may be passed between a pair of pressing surfaces and continuously pressed to form a film.

At this time, the unit for supplying the liquid crystal polymer (melt) in a molten state is not particularly limited. For example, as a specific unit for supplying the melt, an extruder which melts the liquid crystal polymer and extrudes it into a film may be used, an extruder and a die may be used, or the liquid crystal polymer may be once solidified into a film and then molten by a heating unit to form a melt, which may be supplied to the film producing step.

In a case where the molten resin extruded from the die into a sheet is pressed by a device having a pair of pressing surfaces, the surface morphology of the pressing surface can be transferred to the film, as well as the aligning properties can be controlled by imparting elongation deformation to the composition including the liquid crystal polymer.

Film Producing Method and Type

Among the methods for forming a raw material in a molten state into a film, it is preferable to pass between two rolls (for example, a touch roll and a chill roll) from the viewpoint that a high pressing pressure can be applied and the film surface shape is excellent. Furthermore, in the present specification, in a case where a plurality of cast rolls for transporting the melt are provided, the cast roll closest to a supply unit (for example, a die) for the most upstream liquid crystal polymer is referred to as a chill roll. In addition, a method of pressing metal belts with each other or a method of combining a roll and a metal belt can also be used. In addition, in some cases, in order to improve the adhesiveness with rolls or metal belts, a film producing method such as a static electricity application method, an air knife method, an air chamber method, and a vacuum nozzle method can be used in combination on a cast drum.

In addition, in a case of obtaining a film having a multilayer structure, it is preferable to obtain the polymer film by pressing a molten polymer extruded from a die in multiple layers, but it is also possible to obtain a film having a multilayer structure by introducing a film having a monolayer structure into a pressing portion in the same manner as for molten laminating. In addition, at this time, films having different inclined structures in the thickness direction can be obtained by changing a circumferential speed difference or an alignment axis direction of the pressing portion, and films having three or more layers can be obtained by performing this step several times.

Furthermore, the touch roll may be periodically vibrated in the TD direction in a case of pressing to afford deformation.

Temperature of Molten Polymer

From the viewpoints of the improvement of the moldability of the liquid crystal polymer and the suppression of deterioration, a discharge temperature (resin temperature at an outlet of the supply unit) is preferably (Tm of liquid crystal polymer−10°) C to (Tm of liquid crystal polymer+40°) C. A guide for the melt viscosity is preferably 50 to 3,500 Pa·s.

It is preferable that the cooling of the molten polymer between the air gaps is as small as possible, and it is preferable to reduce a temperature drop due to the cooling by taking measures such as increasing the film producing speed and shortening the air gap.

Temperature of Touch Roll

A temperature of the touch roll is preferably set to Tg or less of the liquid crystal polymer. In a case where the temperature of the touch roll is Tg or less of the liquid crystal polymer, pressure-sensitive adhesion of the molten polymer to the roll can be suppressed, and therefore, the film appearance is improved. For the same reason, the chill roll temperature is preferably set to Tg or less of the liquid crystal polymer.

(Film Producing Procedure for Polymer Film)

Film Producing Procedure

In the film producing step, it is preferable to perform the film production by the following procedure from the viewpoints of the film producing step for a film and the stabilization of quality.

The molten polymer discharged from the die is landed on a cast roll to form a film, which is then cooled and solidified and wound up as a film.

In a case of pressing the molten polymer, the molten polymer is passed between the first pressing surface and the second pressing surface set at a predetermined temperature, which is then cooled and solidified and wound up as a film.

(Stretching Step, Thermal Relaxation Treatment, and Thermal Fixation Treatment)

Furthermore, after producing a non-stretched film by the method, the non-stretched film may be continuously or discontinuously stretched and/or subjected to a thermal relaxation treatment or a thermal fixation treatment. For example, each step can be carried out by the combination of the following (a) to (g). In addition, the order of the machine-direction stretching and the cross-direction stretching may be reversed, each step of the machine-direction stretching and the cross-direction stretching may be performed in multiple stages, and each step of the machine-direction stretching and the cross-direction stretching may be combined with oblique-direction stretching or simultaneous biaxial stretching.
(a) Cross-direction stretching
(b) Cross-direction stretching→Thermal relaxation treatment
(c) Machine-direction stretching
(d) Machine-direction stretching→Thermal relaxation treatment
(e) Machine-direction (cross-direction) stretching→Cross-direction (machine-direction) stretching
(f) Machine-direction (cross-direction) stretching→Cross-direction (machine-direction) stretching→Thermal relaxation treatment
(g) Cross-direction stretching→Thermal relaxation treatment→Machine-direction stretching→Thermal relaxation treatment

Machine-Direction Stretching

The machine-direction stretching can be achieved by making the circumferential speed on the outlet side faster than the circumferential speed on the inlet side while heating between the two pairs of rolls. From the viewpoint of a curl of a film, it is preferable that the film temperatures are the same on the front and back surfaces, but in a case where optical characteristics are controlled in the thickness direction, the stretching can be performed at different temperatures on the front and back surfaces. Furthermore, the stretching temperature herein is defined as a temperature on the lower side of the film surface. The machine-direction stretching step may be carried out in either one step or multiple steps. The preheating of the film is generally performed by passing it through a temperature-controlled heating roll, but in some cases, a heater can be used to heat the film. In addition, a ceramic roll or the like having improved adhesiveness can also be used in order to prevent the film from pressure-sensitive adhesiveness to the roll.

Cross-Direction Stretching

As the cross-direction stretching step, normal cross-direction stretching can be adopted. That is, examples of the normal cross-direction stretching include a stretching method in which both ends in the width direction of the film are gripped with clips, and the clips are widened while being heated in an oven using a tenter. With regard to the cross-direction stretching step, for example, methods described in JP1987-035817U (JP-S62-035817U), JP2001-138394A, JP1998-249934A (JP-H10-249934A), JP1994-270246A (JP-H06-270246A), JP1992-030922U (JP-H04-030922U), and JP1987-152721A (JP-S62-152721A) can be used, and these methods are herein incorporated by reference.

A stretching ratio (cross-direction stretching ratio) in the width direction of the film in the cross-direction stretching step is preferably 1.2 to 6 times, more preferably 1.5 to 5 times, and still more preferably 2 to 4 times. In addition, the cross-direction stretching ratio is preferably larger than the stretching ratio of the machine-direction stretching in a case where the machine-direction stretching is performed.

A stretching temperature in the cross-direction stretching step can be controlled by blowing air at a desired temperature into a tenter. The film temperatures may be the same or different on the front and back surfaces for the same reason as in the machine-direction stretching. The stretching temperature used herein is defined as a temperature on the lower side of the film surface. The cross-direction stretching step may be carried out in one step or in multiple steps. In addition, in a case of performing cross-direction stretching in multiple stages, the cross-direction stretching may be performed continuously or intermittently by providing a zone in which widening is not performed. For such the cross-direction stretching, in addition to the normal cross-direction stretching in which a clip is widened in the width direction in a tenter, a stretching method as below, in which a clip is widened by gripping, can also be applied.

Oblique-Direction Stretching

In the oblique-direction stretching step, the clips are widened in the cross-direction in the same manner as in the normal cross-direction stretching, but can be stretched in an oblique direction by switching the transportation speeds of the left and right clips. As the oblique-direction stretching step, for example, the methods described in JP2002-022944A, JP2002-086554A, JP2004-325561A, JP2008-23775A, and JP2008-110573A can be used.

Simultaneous Biaxial Stretching

In the simultaneous biaxial stretching, clips are widened in the cross-direction, and simultaneously stretched or contracted in the machine direction, in a similar manner to the normal cross-direction stretching. As the simultaneous biaxial stretching, for example, the methods described in JP1980-093520U (JP-S55-093520U), JP1988-247021A (JP-S63-247021A), JP1994-210726A (JP-H06-210726A), JP1994-278204A (JP-H06-278204A), JP2000-334832A, JP2004-106434A, JP2004-195712A, JP2006-142595A, JP2007-210306A, JP2005-022087A, and JP2006-517608A can be used.

Heat Treatment to Improve Bowing (Axis Misalignment)

Since the end part of the film is gripped by the clip in the cross-direction stretching step, the deformation of the film due to a thermal contraction stress generated during a heat treatment is large at the center of the film and is small at the end parts, and as a result, the characteristics in the width direction can be distributed. In a case where a straight line is drawn along the cross-direction on a surface of the film before the heat treatment step, the straight line on the surface of the film after the heat treatment step is an arcuate shape in which the center portion is recessed toward the downstream side. This phenomenon is called a bowing phenomenon, and is a cause that disturbs isotropy and widthwise uniformity of the film.

With an improvement method therefor, it is possible to reduce a variation in an alignment angle due to the bowing by performing preheating before the cross-direction stretching or by performing the thermal fixation after the stretching. The preheating and the thermal fixation may be performed, but it is preferable to perform the both. It is preferable to perform the preheating and the thermal fixation by gripping with a clip, that is, it is preferable to perform the preheating and the thermal fixation continuously with the stretching.

The preheating is performed at a temperature higher than the stretching temperature by preferably about 1° C. to 50° C., more preferably 2° C. to 40° C., and still more preferably 3° C. to 30° C. The preheating time is preferably 1 second to 10 minutes, more preferably 5 seconds to 4 minutes, and still more preferably 10 seconds to 2 minutes.

During the preheating, it is preferable to keep the width of the tenter almost constant. The term “almost” as mentioned herein refers to +10% of the width of the non-stretched film.

The thermal fixation is performed at a temperature lower than the stretching temperature by preferably about 1° C. to 50° C., more preferably 2° C. to 40° C., and still more preferably 3° C. to 30° C. Particularly preferably, the temperature is no higher than the stretching temperature and no higher than the Tg of the liquid crystal polymer.

The thermal fixation time is preferably 1 second to 10 minutes, more preferably 5 seconds to 4 minutes, and still more preferably 10 seconds to 2 minutes. During thermal fixation, it is preferable to keep the width of the tenter almost constant. The term “almost” as mentioned herein means 0% (the same width as the tenter width after stretching) to −30% (30% smaller than the tenter width after stretching=reduced width) of the tenter width after the completion of stretching. Examples of other known methods include the methods described in JP1989-165423A (JP-H01-165423A), JP1991-216326A (JP-H03-216326A), JP2002-018948A, and JP2002-137286A.

Thermal Relaxation Treatment

After the stretching step, a thermal relaxation treatment in which the film is heated to contract the film may be performed. By performing the thermal relaxation treatment, the thermal contraction rate at the time of using the film can be reduced. It is preferable that the thermal relaxation treatment is carried out at at least one timing of a time after film production, a time after machine-direction stretching, or a time after cross-direction stretching.

The thermal relaxation treatment may be continuously performed online after the stretching, or may be performed offline after winding after the stretching. Examples of the temperature of the thermal relaxation treatment include a temperature from a glass transition temperature Tg to a melting point Tm of the liquid crystal polymer. In a case where there is a concern about oxidative deterioration of the film, the thermal relaxation treatment may be performed in an inert gas such as a nitrogen gas, an argon gas, and a helium gas.

(Post-Heating Treatment)

An unstretched film formed by the method or a film which has been subjected to machine-direction stretching may be subjected to cross-direction stretching and then subjected to a post-heating treatment in which the film is heated while fixing the film width.

In the post-heating treatment, a heat treatment is performed while fixing the film width by a fixing method such as gripping both ends of a film in a width direction with clips. The film width after the post-heating treatment is preferably 85% to 105%, and more preferably 95% to 102% with respect to the film width before the post-heating treatment.

The heating temperature in the post-heating treatment is preferably {Tm−200}° C. or higher, more preferably {Tm−100}° C. or higher, and still more preferably {Tm−50}° C. or higher, with the melting point of the liquid crystal polymer being taken as the Tm (° C.). Alternatively, the heating temperature in the post-heating treatment is preferably 240° C. or higher, more preferably 255° C. or higher, and still more preferably 270° C. or higher. The upper limit of the heating temperature in the post-heating treatment is preferably {Tm}° C. or lower, more preferably {Tm−2}° C. or lower, and still more preferably {Tm−5}° C. or lower.

Examples of the heating unit used for the post-heating treatment include a hot air dryer and an infrared heater, and the infrared heater is preferable since a film having a desired melting peak surface area can be produced in a short time. In addition, as the heating unit, pressurized steam, microwave heating, and a heat medium circulation heating method may be used.

A treatment time for the post-heating treatment can be appropriately adjusted according to the type of a liquid crystal polymer, a target melting peak surface area, a heating unit, and a heating temperature, and in a case where the infrared heater is used, the treatment time is preferably 1 to 120 seconds, and more preferably 3 to 90 seconds. In addition, in a case where the hot air dryer is used, the treatment time is preferably 0.5 to 30 minutes, and more preferably 1 to 10 minutes.

(Surface Treatment)

From the viewpoint that the adhesiveness between the polymer film and the resin layer can be further improved and the adhesiveness of the metal layer in the laminate can be further improved, it is preferable to subject the polymer film to a surface treatment. Examples of the surface treatment include a glow discharge treatment, an ultraviolet irradiation treatment, a corona treatment, a flame treatment, and an acid or alkali treatment. The glow discharge treatment as mentioned herein may be a treatment with a low-temperature plasma generated under a gas at a low pressure ranging from 10⁻³ to 20 Torr, and is preferably a plasma treatment under atmospheric pressure.

The glow discharge treatment is performed using a plasma-excited gas. The plasma-excited gas refers to a gas that is plasma-excited under the above-described conditions, and examples thereof include argon, helium, neon, krypton, xenon, nitrogen, and carbon dioxide, fluorocarbons such as tetrafluoromethane, and mixtures of these.

It is also useful to subject the polymer film to an aging treatment at a temperature which is temperature equal to or lower than the Tg of the liquid crystal polymer in order to improve the mechanical properties, thermal dimensional stability, or winding shape of the wound polymer film.

In addition, with regard to the polymer film, the smoothness of the film may be further improved through a step of compressing the film with a heating roll and/or a step of stretching the film after performing the film producing step.

In the manufacturing method, the case where the polymer film is a single layer is described, but the polymer film may have a laminated structure in which a plurality of layers are laminated.

[Adhesive Layer]

The adhesive layer is arranged on the polymer film, and is preferably arranged so as to be in contact with the polymer film. The adhesive layer may be arranged on one side of the polymer film or may be arranged on both sides of the polymer film.

<Compound Having Reactive Group>

The adhesive layer includes a compound having a reactive group (hereinafter also referred to as a “reactive compound”).

The reactive group is preferably a group capable of reacting with a group which may be present on a surface of the polymer film (in particular, a group having an oxygen atom, such as a carboxy group and a hydroxyl group).

From the viewpoint that the effect of the present invention is more excellent, the reactive group is preferably at least one group selected from the group consisting of an epoxy group, an oxetanyl group, an isocyanate group, an acid anhydride group, a carbodiimide group, an N-hydroxyester group, a glyoxal group, an imide ester group, an alkyl halide group, and a thiol group, preferably at least one group selected from the group consisting of the epoxy group, the acid anhydride group, and the carbodiimide group, and more preferably the epoxy group.

Specific examples of the reactive compound having an epoxy group include aromatic glycidylamine compounds (for example, N,N-diglycidyl-4-glycidyloxyaniline, 4,4′-methylenebis(N,N-diglycidylaniline), N,N-diglycidyl-o-toluidine, N,N,N′,N′-tetraglycidyl-m-xylene diamine, 4-t-butylphenylglycidyl ether), aliphatic glycidylamine compounds (for example, 1,3-bis(diglycidylaminomethyl)cyclohexane), and aliphatic glycidyl ether compounds (for example, sorbitol polyglycidyl ether). Among these, the aromatic glycidylamine compounds are preferable from the viewpoint that the effect of the present invention is more excellent.

Specific examples of the reactive compound having an acid anhydride group include tetracarboxylic acid dianhydrides (for example, 3,3′,4,4′-benzophenone tetracarboxylic acid dianhydride, 3,3′,4,4′-biphenyltetracarboxylic acid dianhydride, pyromellitic acid dianhydride, 2,3,3′,4′-biphenyltetracarboxylic acid dianhydride, oxydiphthalic acid dianhydride, diphenylsulfone-3,4,3′,4′-tetracarboxylic acid dianhydride, bis(3,4-dicarboxyphenyl)sulfide dianhydride, 2,2-bis(3,4-dicarboxyphenyl)-1,1,1,3,3,3-hexafluoropropane dianhydride, 2,3,3′,4′-benzophenone tetracarboxylic acid dianhydride, bis(3,4-dicarboxyphenyl)methane dianhydride, 2,2-bis(3,4-dicarboxyphenyl)propane dianhydride, p-phenylenebis(trimellitic acid monoester anhydride), p-biphenylenebis(trimellitic acid monoester anhydride), m-terphenyl-3,4,3′,4′-tetracarboxylic acid dianhydride, p-terphenyl-3,4,3′,4′-tetracarboxylic acid dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy)biphenyl dianhydride, 2,2-bis[(3,4-dicarboxyphenoxy)phenyl]propane dianhydride, 2,3,6,7-naphthalenetetracarboxylic acid dianhydride, 1,4,5,8-naphthalenetetracarboxylic acid dianhydride, and 4,4′-(2,2-hexafluoroisopropyridene)diphthalic acid dianhydride).

Specific examples of the reactive compound having a carbodiimide group include monocarbodiimide compounds (for example, dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphthylcarbodiimide, N,N′-di-2,6-diisopropylphenylcarbodiimide), and polycarbodiimide compounds (for example, compounds produced by the methods described in U.S. Pat. No. 2,941,956A, JP1972-33279B (JP-S47-33279B), J. Org. Chem. 28, p. 2069-2075 (1963), Chemical Review 1981, 81, No. 4, p. 619-621, and the like).

Examples of a commercially available product of the reactive compound having a carbodiimide group include Carbodilite HMV-8CA, LA-1, V-03 (manufactured by Nisshinbo Chemical Inc.), Stabaxol P, P100, P400 (manufactured by Rhein Chemie Japan Ltd.), and Stabilizer 9000 (manufactured by Rhein Chemie Corporation).

The number of the reactive groups contained in the reactive compound is 1 or more, but from the viewpoint that the adhesiveness of the metal layer is more excellent, the number of the reactive groups is preferably 3 or more.

The number of the reactive groups contained in the reactive compound is preferably 6 or less, more preferably 5 or less, and still more preferably 4 or less from the viewpoint that a laminate having a lower dielectric loss tangent of a portion other than the metal layer can be obtained.

The content of the reactive compound is preferably 0.1% to 40% by mass, more preferably 1% to 30% by mass, and still more preferably 3% to 20% by mass with respect to the total mass of the adhesive layer. In a case where the content is equal to or higher than the lower limit value, the adhesiveness of the metal layer is more excellent, and in a case where the content is equal to or lower than the upper limit value, a laminate having a lower dielectric loss tangent of a portion other than the metal layer can be obtained.

<Binder Resin>

The adhesive layer preferably includes a binder resin.

Specific examples of the binder resin include a (meth)acrylic resin, a polyvinyl cinnamate, a polycarbonate, a polyimide, a polyamidoimide, a polyesterimide, a polyetherimide, a polyether ketone, a polyether ether ketone, a polyethersulfone, a polysulfone, a polyparaxylene, a polyester, a polyvinyl acetal, a polyvinyl chloride, a polyvinyl acetate, a polyamide, a polystyrene, a polyurethane, a polyvinyl alcohol, a cellulose acylate, a fluororesin, a liquid crystal polymer, a syndiotactic polystyrene, a silicone resin, an epoxy silicone resin, a phenol resin, an alkyd resin, an epoxy resin, a maleic acid resin, a melamine resin, a urea resin, an aromatic sulfonamide, a benzoguanamine resin, a silicone elastomer, an aliphatic polyolefin (for example, polyethylene and polypropylene), and a cyclic olefin copolymer. Among these, the polyimide, the liquid crystal polymer, the syndiotactic polystyrene, or the cyclic olefin copolymer is preferable, and the polyimide is more preferable from the viewpoint that the effect of the present invention is more excellent.

The content of the binder resin is preferably 60% to 99.9% by mass, more preferably 70% to 99.0% by mass, and still more preferably 80% to 97.0% by mass with respect to the total mass of the adhesive layer.

<Additive>

The adhesive layer may include a component (hereinafter also referred to as an “additive”) other than the reactive compound and the binder resin.

Examples of the additive include an inorganic filler, a curing catalyst, and a flame retardant.

The content of the additive is preferably 0.1% to 40% by mass, more preferably 1% to 30% by mass, and still more preferably 3% to 20% by mass with respect to the total mass of the adhesive layer.

<Physical Properties of Adhesive Layer>

(Thickness)

The thickness of the adhesive layer is 1 μm or less, and from the viewpoint that a laminate having a lower standard dielectric loss tangent of a portion other than the metal layer can be formed, the thickness of the adhesive layer is preferably 0.8 μm or less, more preferably 0.7 μm or less, and still more preferably 0.6 μm or less.

From the viewpoint that the adhesiveness of the metal layer is more excellent, the thickness of the adhesive layer is preferably 0.05 μm or more, more preferably 0.1 μm or more, and still more preferably 0.2 μm or more.

The thickness of the adhesive layer is measured based on a cross-sectional image of the polymer film with the adhesive layer by a scanning electron microscope (SEM), and is an arithmetic average value of the values measured as a thickness of the adhesive layer at any different 100 points.

(Elastic Modulus)

The post-curing elastic modulus of the adhesive layer is 0.8 GPa or more, and from the viewpoint that the adhesiveness of the metal layer is more excellent, the post-curing elastic modulus of the adhesive layer is preferably 1.0 GPa or more, more preferably 1.1 GPa or more, and still more preferably 1.2 GPa or more.

The lower limit value of the post-curing elastic modulus of the adhesive layer is not particularly limited, and is, for example, 5 GPa or less.

The post-curing elastic modulus of the adhesive layer is an indentation elastic modulus measured according to ISO14577, and a specific measurement method therefor is described in the section of Examples which will be described later.

(Standard Dielectric Loss Tangent)

The standard post-curing dielectric loss tangent of the adhesive layer is preferably 0.01 or less, more preferably 0.008 or less, and still more preferably 0.005 or less from the viewpoint that a laminate having a lower standard dielectric loss tangent of a portion other than the metal layer can be formed. The lower limit value is not particularly limited, and may be 0.0001 or more.

The standard post-curing dielectric loss tangent of the adhesive layer is measured by a cavity resonator perturbation method, and a specific measurement method therefor will be described in the section of Examples which will be described later.

A second embodiment of the polymer film with an adhesive layer of the present invention is a polymer film with an adhesive layer, including a polymer film having a standard dielectric loss tangent of 0.005 or less, and the adhesive layer arranged on the polymer film. In addition, in a case where a surface of the polymer film on a side of the adhesive layer is measured by X-ray photoelectron spectroscopy, an atomic ratio of oxygen atoms to carbon atoms is 0.27 or more. Furthermore, the adhesive layer includes a compound having a reactive group. Moreover, the adhesive layer has a thickness of 1 μm or less. In addition, the adhesive layer has a post-curing elastic modulus of 0.8 GPa or more.

The first embodiment of the polymer film with an adhesive layer of the present invention and the second embodiment of the polymer film with an adhesive layer of the present invention have the same configuration, except that the second embodiment of the polymer film with an adhesive layer of the present invention includes a polymer film having a standard dielectric loss tangent of 0.005 or less.

The standard dielectric loss tangent of the polymer film in the second embodiment of the polymer film with an adhesive layer of the present invention is 0.005 or less, and a suitable range thereof is the same as the preferred range of the standard dielectric loss tangent of the polymer film in the first embodiment of the polymer film with an adhesive layer described above.

The dielectric characteristics including a dielectric loss tangent and a relative permittivity of the polymer film can be measured by a cavity resonator perturbation method. A specific method for measuring the dielectric characteristics of the polymer film will be described in the section of Examples which will be described later.

The polymer film in the second embodiment of the polymer film with an adhesive layer of the present invention preferably includes a polymer having a standard dielectric loss tangent of 0.005 or less included in the polymer film in the first embodiment of the polymer film with an adhesive layer of the present invention. The aspect of the polymer having a standard dielectric loss tangent of 0.005 or less is as described above.

A suitable aspect of the material included in the polymer film in the second embodiment of the polymer film with an adhesive layer of the present invention is the same as the suitable range of the material included in the polymer film in the first embodiment of the polymer film with an adhesive layer of the present invention. For example, the polymer film in the second embodiment of the polymer film with an adhesive layer of the present invention may include <Optional Components> which may be included in the polymer film in the first embodiment of the polymer film with an adhesive layer of the present invention.

In addition, a suitable range of the characteristics (for example, a thickness) of the polymer film in the second embodiment of the polymer film with an adhesive layer of the present invention has the same as the preferred range of the characteristics (for example, a thickness) of the polymer film in the first embodiment of the polymer film with an adhesive layer of the present invention.

[Method for Producing Polymer Film with Adhesive Layer]

The method for producing a polymer film with an adhesive layer according to an embodiment of the present invention is not particularly limited, and for example, a polymer film having an adhesive layer, having the polymer film and the adhesive layer, can be produced by attaching a composition for forming an adhesive layer onto the polymer film, and drying the composition for forming an adhesive layer attached on the polymer film, as necessary.

The composition for forming an adhesive layer includes a reactive compound, and may include a binder resin, an additive, a solvent, and the like. The reactive compound, the binder resin, and the additive are as described above, and thus, descriptions thereof will be omitted.

Examples of the solvent include water and an organic solvent, and a mixed solvent of water and the organic solvent may be used.

Examples of the organic solvent include esters (for example, ethyl acetate, n-butyl acetate, and isobutyl acetate) and ethers (for example, ethylene glycol dimethyl ether, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, and diethylene glycol monoethyl ether), ketones (for example, methyl ethyl ketone, cyclohexanone, cyclopentanone, 2-heptanone, and 3-heptanone), hydrocarbons (hexane, cyclohexane, methylcyclohexane), and aromatic hydrocarbons (for example, toluene and xylene).

The content of the reactive compound is preferably 0.1% to 40% by mass, more preferably 1% to 30% by mass, and still more preferably 3% to 20% by mass with respect to the total mass of the composition for forming an adhesive layer.

The content of the binder resin is preferably 60% to 99.9% by mass, more preferably 70% to 99% by mass, and still more preferably 80% to 97% by mass with respect to the total mass of the composition for forming an adhesive layer.

The content of the additive is preferably 0.1% to 40% by mass, more preferably 1% to 30% by mass, and still more preferably 3% to 20% by mass with respect to the total mass of the composition for forming an adhesive layer.

A method for attaching the composition for forming an adhesive layer onto the polymer film is not particularly limited, and examples thereof include a bar coating method, a spray coating method, a squeegee coating method, a flow coating method, a spin coating method, a dip coating method, a die coating method, an ink jet method, and a curtain coating method.

In a case where the composition for forming an adhesive layer attached onto the polymer film is dried, the drying conditions are not particularly limited, but the drying temperature is preferably 25° C. to 200° C. and the drying time is preferably 1 second to 120 minutes.

[Laminate]

A first embodiment of the laminate of the present invention has a polymer film including a polymer having a standard dielectric loss tangent of 0.005 or less, a resin layer arranged on the polymer film, and a metal layer arranged on the resin layer. Furthermore, in a case where a surface of the polymer film on a side of the resin layer is measured by X-ray photoelectron spectroscopy, an atomic ratio of oxygen atoms to carbon atoms is 0.27 or more. Moreover, the thickness of the resin layer is 1 μm or less. In addition, the elastic modulus of the resin layer is 0.8 GPa or more.

[Polymer Film]

The polymer film contained in the first embodiment of the laminate of the present invention is the same as in the above-mentioned first embodiment of the polymer film, and thus, a description thereof will be omitted.

[Resin Layer]

The resin layer is arranged on the polymer film, and is preferably arranged so as to be in contact with the polymer film. The resin layer may be arranged on one side of the polymer film or may be arranged on both sides of the polymer film.

The resin layer is preferably a layer obtained by curing the above-mentioned adhesive layer.

The resin layer preferably includes a reaction product of the above-mentioned reactive compound. Examples of the reaction product of the reactive compound include a reaction product obtained by reacting a reactive group of the reactive compound reacts with a group including an oxygen atom present on a surface of the polymer film.

The content of the reaction product of the reactive compound with respect to the total mass of the resin layer is preferably the same as the content of the reactive compound with respect to the total mass of the adhesive layer.

The resin layer preferably includes the above-described binder resin.

The content of the binder resin with respect to the total mass of the resin layer is preferably the same as the content of the binder resin with respect to the total mass of the adhesive layer.

The resin layer may include the above-mentioned additive.

The content of the additive with respect to the total mass of the resin layer is preferably the same as the content of the additive with respect to the total mass of the adhesive layer.

The thickness of the resin layer is 1 μm or less, and from the viewpoint that a laminate having a lower standard dielectric loss tangent of a portion other than the metal layer can be formed, the thickness of the adhesive layer is preferably 0.8 μm or less, more preferably 0.7 μm or less, and still more preferably 0.6 μm or less.

From the viewpoint that the adhesiveness of the metal layer is more excellent, the thickness of the resin layer is preferably 0.05 μm or more, more preferably 0.1 μm or more, and still more preferably 0.2 μm or more.

The thickness of the resin layer is measured based on a cross-sectional image of the laminate by a scanning electron microscope (SEM), and is an arithmetic average value of values measured as a thickness of the resin layer at any different 100 points.

The elastic modulus of the resin layer is 0.8 GPa or more, and from the viewpoint that the adhesiveness of the metal layer is more excellent, the post-curing elastic modulus of the adhesive layer is preferably 1.0 GPa or more, more preferably 1.1 GPa or more, and still more preferably 1.2 GPa or more.

The lower limit value of the elastic modulus of the resin layer is not particularly limited, and is, for example, 5 GPa or less.

The elastic modulus of the resin layer is an indentation elastic modulus measured according to ISO14577, and a specific measurement method therefor is described in the section of Examples which will be described later.

The standard dielectric loss tangent of the resin layer is preferably 0.01 or less, more preferably 0.008 or less, and still more preferably 0.005 or less from the viewpoint that a laminate having a lower standard dielectric loss tangent of a portion other than the metal layer can be obtained. The lower limit value is not particularly limited, and may be 0.0001 or more.

The standard dielectric loss tangent of the resin layer is measured by a cavity resonator perturbation method, and a specific measurement method therefor will be described in the section of Examples which will be described later.

[Metal Layer]

The metal layer is arranged on the resin layer, and is preferably arranged so as to be in contact with the resin layer. In a case where the resin layers are arranged on both surfaces of the polymer film, the metal layer may be arranged only on one resin layer or may be arranged on both the resin layers.

As the material forming the metal layer, a metal used for electrical connection is preferable. Examples of such metals include copper, gold, silver, nickel, aluminum, and alloys including any of these metals. Examples of the alloy include a copper-zinc alloy, a copper-nickel alloy, and a zinc-nickel alloy.

As the metal layer, a copper layer is preferable from the viewpoint that the conductivity and the workability are excellent. The copper layer is a layer consisting of copper or a copper alloy including 95% by mass or more of copper. Examples of the copper layer include a rolled copper foil produced by a rolling method, and an electrolytic copper foil produced by an electrolysis method. The metal layer may be subjected to a chemical treatment such as acid cleaning.

A thickness of the metal layer is not particularly limited, and is appropriately selected depending on a use of a circuit board, but the thickness is preferably 2 to 100 μm, and more preferably 10 to 35 μm from the viewpoints of wiring line conductivity and economical efficiency.

The maximum height Rz of the surface of the metal layer on a side of the resin layer is preferably 5.0 μm or less, more preferably 4.0 μm or less, still more preferably 3.0 μm or less, and particularly preferably 2.0 μm or less from the viewpoint that the transmission loss of a laminate in a case of being used as a communication circuit board can be reduced.

The lower limit is not particularly limited, but is preferably 0.1 μm or more, and more preferably 0.6 μm or more.

The maximum height Rz on a surface of the metal layer is determined by measuring a maximum height Rz at any 30 points and arithmetically averaging the values obtained from the measurement, using a stylus type roughness meter according to JIS B0601, on a surface of the metal layer peeled from the laminate, on a side of the resin layer.

In a case where a commercially available metal foil is used as the metal layer, a numerical value of the maximum height Rz described as a catalog value of the commercially available product may be used.

A peel strength in a case where the metal layer is peeled from the laminate is preferably 0.50 kN/m or more, more preferably 0.60 kN/m or more, still more preferably 0.65 kN/m or more, and particularly preferably 0.70 kN/m or more. The more the peel strength, the more excellent the adhesiveness between the polymer film and the metal layer.

The upper limit value of the peel strength is not particularly limited and may be 2.0 kN/m or less.

A method for measuring the peel strength will be described in the section of Examples which will be described later.

The standard dielectric loss tangent of a dielectric (a portion other than the metal layer constituting the laminate, in which examples of the portion include a resin layer and a polymer film) constituting the laminate is preferably 0.0024 or less, more preferably 0.0020 or less, and still more preferably 0.0010 or less. The lower limit value is not particularly limited, and may be 0.0001 or more.

The standard dielectric loss tangent of the dielectric is measured by a cavity resonator perturbation method, and a specific measurement method therefor will be described in the section of Examples which will be described later.

The laminate may have a layer other than the polymer film, the resin layer, and the metal layer, as necessary. Examples of the other layer include a rust preventive layer and a heat resistant layer.

A second embodiment of the laminate of the present invention has a polymer film having a standard dielectric loss tangent of 0.005 or less, a resin layer arranged on the polymer film, and a metal layer arranged on the resin layer. Furthermore, in a case where a surface of the polymer film on a side of the resin layer is measured by X-ray photoelectron spectroscopy, an atomic ratio of oxygen atoms to carbon atoms is 0.27 or more. Moreover, the thickness of the resin layer is 1 μm or less. In addition, the elastic modulus of the resin layer is 0.8 GPa or more.

The first embodiment of the laminate of the present invention and the second embodiment of the laminate of the present invention have the same configuration, except that the second embodiment of the laminate of the present invention includes a polymer film having a standard dielectric loss tangent of 0.005 or less.

In addition, the polymer film included in the second embodiment of the laminate of the present invention is the same as in the above-mentioned second embodiment of the polymer film, and thus a description thereof will be omitted.

[Method for Producing Laminate]

The method for producing a laminate of an embodiment of the present invention has a step of attaching a composition for forming an adhesive layer, including a reactive compound, onto a polymer film to obtain a polymer film with the adhesive layer, in which the adhesive layer is arranged on the polymer film (hereinafter also referred to as a “step 1”), and a step of arranging a metal foil on the adhesive layer in the polymer film with the adhesive layer, and thermocompression-bonding the adhesive layer and the metal foil to each other to form a metal layer on a resin layer obtained by curing the adhesive layer (hereinafter also referred to as a “step 2”).

<Step 1>

Since the step 1 is the same as in the above-mentioned method for producing the polymer film with an adhesive layer, a description thereof will be omitted.

<Step 2>

The methods and the conditions for the thermocompression-bonding the adhesive layer and the metal foil to each other in the step 2 are not particularly limited, and are appropriately selected from known methods and conditions. The temperature condition for the thermocompression-bonding is preferably 100° C. to 300° C., and the pressure condition for the thermocompression-bonding is preferably 0.1 to 20 MPa.

By the thermocompression-bonding according to the step 2, the adhesive layer is cured to form a resin layer, and a metal layer obtained by thermocompression-bonding the metal foil is formed on the resin layer.

Examples of the use of the laminate include a laminated circuit board, a flexible laminated board, and a wiring substrate such as a flexible printed circuit (FPC). The laminate is particularly preferably used as a high-speed communication substrate.

### EXAMPLES

Hereinbelow, the present invention will be described in more detail with reference to Examples. The materials, the amounts of materials used, the ratios, the treatment details, the treatment procedure, or the like shown in the following Examples can be appropriately modified without departing from the spirit of the present invention. Therefore, the scope of the present invention should not be restrictively interpreted by the following Examples.

### Example 1

<Manufacture of Film>

One surface of a polymer film (“VECSTAR CTQ-25” manufactured by Kuraray Co., Ltd., a thickness of 25 μm, a polymer film including a liquid crystal polymer) was subjected to an atmospheric pressure plasma treatment (11 kV, 16 mm/s, 1 round, He or N₂ plasma) to manufacture a polymer film 1 (thickness: 25 μm).

The standard dielectric loss tangent of the liquid crystal polymer included in the polymer film 1 was measured according to the above-described method and found to be 0.0021.

<Manufacture of Laminate>

17.7 g of a polyimide resin solution (“PIAD-200” manufactured by Arakawa Chemical Industries, Ltd., solid content of 30% by mass, solvents: cyclohexane, methylcyclohexane, and ethylene glycol dimethyl ether), 0.27 g of N,N-diglycidyl-4-glycidyloxyaniline (manufactured by Sigma-Aldrich), and 1.97 g of toluene were mixed and stirred to obtain an adhesive varnish 1 (composition for forming an adhesive layer) having a concentration of solid contents of 28% by mass.

The obtained adhesive varnish was applied onto the surface of the polymer film 1, which had been subjected to a surface treatment, using an applicator. The coating film was dried under the conditions of 85° C. for 1 hour to provide an adhesive layer having a thickness of 0.8 μm, and a polymer film 1 with an adhesive layer was manufactured.

The polymer film 1 with an adhesive layer and a non-roughening-treated copper foil (“CF-T₉DA-SV-18” manufactured by Fukuda Metal Foil & Powder Co., Ltd., a thickness of 18 μm) were laminated so that the adhesive layer of the polymer film 1 with the adhesive layer and the non-roughening-treated surface (maximum height Rz of 0.85 μm) of the non-roughening-treated copper foil were in contact with each other, and then compression-bonded for 1 hour under the conditions of 200° C. and 4 MPa using a hot press machine (Toyo Seiki Seisaku-sho, Ltd.) to obtain a laminate 1 in which the polymer film 1, the resin layer (cured film with the adhesive layer), and the metal layer (copper foil) were laminated in this order.

### Examples 2 and 3

A polymer film with an adhesive layer and a laminate of each of Examples 2 and 3 were obtained according to the same method as described in Example 1, except that the coating amount of the adhesive varnish 1 was adjusted so that the thickness of the adhesive layer was as shown in Table 1.

### Example 4

15.9 g of a polyimide resin solution (the above-mentioned “PIAD-200”), 0.88 g of N,N-diglycidyl-4-glycidyloxyaniline, and 3.19 g of toluene were mixed and stirred to obtain an adhesive varnish 2 (composition for forming an adhesive layer) having a concentration of solid contents of 28% by mass.

A polymer film with an adhesive layer and a laminate of Example 4 were obtained according to the same method as described in Example 1, except that the adhesive varnish 2 was used instead of the adhesive varnish 1.

### Example 5

A polyimide resin solution (the above-mentioned “PIAD-200”), N,N-diglycidyl-4-glycidyloxyaniline, and toluene were mixed and stirred to obtain an adhesive varnish 3 (composition for forming an adhesive layer) having a concentration of solid contents of 28% by mass. Furthermore, the addition amount of each component was appropriately adjusted so that the solid content of the polyimide resin solution and the solid content of N, N-diglycidyl-4-glycidyloxyaniline were the values shown in Table 1.

A polymer film with an adhesive layer and a laminate of Example 5 were obtained according to the same method as described in Example 1, except that the adhesive varnish 3 was used instead of the adhesive varnish 1.

### Example 6

One surface of a polymer film (the above-mentioned “VECSTAR CTQ-25”) was subjected to a corona treatment (“TEC-4AX” manufactured by Kasuga Denki, Inc., 150 W, 0.5 m/min, 6 rounds) to manufacture a polymer film 2. The standard dielectric loss tangent of the liquid crystal polymer included in the polymer film 2 was measured according to the above-described method and found to be 0.0021.

A polymer film with an adhesive layer and a laminate of Example 6 were obtained according to the same method as described in Example 1, except that the polymer film 2 was used instead of the polymer film 1.

### Example 7

17.7 g of a polyimide resin solution (the above-mentioned “PIAD-200”), 0.27 g of 4-t-butylphenylglycidyl ether (manufactured by Tokyo Chemical Industry Co., Ltd.), and 1.97 g of toluene were mixed and stirred to obtain an adhesive varnish 4 having a concentration of solid contents of 28% by mass.

A polymer film with an adhesive layer and a laminate of Example 7 were obtained according to the same method as described in Example 1, except that the adhesive varnish 4 was used instead of the adhesive varnish 1.

### Example 8

17.7 g of a polyimide resin solution (the above-mentioned “PIAD-200”), 0.27 g of Carbodilite V-03 (manufactured by Nisshinbo Chemical Inc., concentration of solid contents: 50% by mass, solvent: toluene, reactive compound having a carbodiimide group), and 1.97 g of toluene were mixed and stirred to obtain an adhesive varnish 5 having a concentration of solid contents of 28% by mass.

A polymer film with an adhesive layer and a laminate of Example 8 were obtained according to the same method as described in Example 1, except that the adhesive varnish 5 was used instead of the adhesive varnish 1.

### Example 9

17.7 g of a polyimide resin solution (the above-mentioned “PIAD-200”), 0.27 g of 3,3′,4,4′-benzophenonetetracarboxylic acid dianhydride (manufactured by Tokyo Chemical Industry Co., Ltd.), and 1.97 g of toluene were mixed and stirred to obtain an adhesive varnish 6 having a concentration of solid contents of 28% by mass.

A polymer film with an adhesive layer and a laminate of Example 9 were obtained according to the same method as described in Example 1, except that the adhesive varnish 6 was used instead of the adhesive varnish 1.

### Comparative Example 1

A polymer film with an adhesive layer and a laminate of Comparative Example 1 were obtained according to the same method as described in Example 1, except that a polymer film which had not been subjected to a surface treatment (the above-mentioned “VECSTAR CTQ-25”) was used instead of the polymer film 1.

The standard dielectric loss tangent of the liquid crystal polymer included in the polymer film (the above-mentioned “VECSTAR CTQ-25”) was measured according to the above-mentioned method and found to be 0.0021.

### Comparative Example 2

A polymer film with an adhesive layer and a laminate of Comparative Example 2 were obtained according to the same method as described in Example 1, except that a polyimide resin solution (the above-mentioned “PIAD-200”) was used instead of the adhesive varnish 1 as an adhesive varnish 7.

### Comparative Example 3

11.2 g of a polyimide resin solution (the above-mentioned “PIAD-200”), 2.24 g of N,N-diglycidyl-4-glycidyloxyaniline, and 6.55 g of toluene were mixed and stirred to obtain an adhesive varnish 8 (composition for forming an adhesive layer) having a concentration of solid contents of 28% by mass.

A polymer film with an adhesive layer and a laminate of Comparative Example 3 were obtained according to the same method as described in Example 1, except that the adhesive varnish 8 was used instead of the adhesive varnish 1.

### Comparative Example 4

A polymer film with an adhesive layer and a laminate of Comparative Example 4 were obtained according to the same method as described in Example 1, except that the coating amount of the adhesive varnish 1 was adjusted so that the thickness of the adhesive layer was as shown in Table 1.

[Evaluation Tests]

The following evaluation tests were performed on the polymer film with an adhesive layer and the laminate produced by the production method of each of the above-described examples.

<Film Thickness>

The thicknesses of the adhesive layer and the resin layer were determined based on a cross-sectional image of the obtained polymer film with an adhesive layer or laminate by a scanning electron microscope (SEM). Furthermore, an arithmetically average value of the thicknesses of the adhesive layer or the resin layer at any 100 different points was taken as the thickness of the adhesive layer or the resin layer.

<Oxygen Ratio on Surface of Polymer Film>

An atomic ratio of oxygen atoms to carbon atoms on a surface of the polymer film on a side of the adhesive layer (an oxygen ratio on a surface of the polymer film) was measured by using an X-ray photoelectron spectroscopic analyzer (“PHI 5000 VersaProbe II” manufactured by ULVAC-PHI, Inc.).

<Elastic Modulus>

A fluororesin sheet was laminated on a surface of an adhesive layer in the polymer film with the adhesive layer produced by the production method of each example, and then heated by a hot pressing machine (Toyo Seiki Seisaku-sho Co., Ltd.) at 200° C. and 4 MPa for 1 hour to obtain a cured film (resin layer) of the adhesive layer. After peeling the fluororesin sheet, the indentation elastic modulus of the cured film was measured by a nanoindentation method.

The measurement was performed using a Berkovich indenter, and an indentation depth at the maximum load was set to 1/10 of the film thickness of the cured film. Film hardness meter: Using a Fisher Scope HM500 (manufactured by Fisher Instruments Co., Ltd.), 10 points were measured for each under the conditions of a loading time: 10 seconds and an unloading time: 10 seconds, and an arithmetic average value of the 10 points was taken as a post-curing elastic modulus.

<Dielectric Loss Tangent>

The laminate was immersed in a 40% aqueous iron (III) chloride solution (manufactured by FUJIFILM Wako Pure Chemical Corporation, first grade) and the metal layer was dissolved by an etching treatment to manufacture a sample A (with a size of 25 mm×50 mm) having a resin layer provided on a surface of the polymer film. In addition, the metal layer and the resin layer were peeled from the laminate to manufacture a sample B (size: 25 mm×50 mm) consisting of a polymer film.

A network analyzer (“Keysight N5230A” manufactured by KeySight Technologies, Inc.) was connected to a split cylinder type resonator (“CR-728” manufactured by Kanto Electronics Application & Development Inc., a cavity resonator), the sample A or the sample B was inserted thereinto, and a standard dielectric loss tangent (a dielectric loss tangent measured under the conditions of a temperature of 23° C. and a frequency of 28 GHz) was determined using analysis software manufactured by Kanto Electronics Application & Development Inc., based on a change in resonance frequency before and after the insertion. The standard dielectric loss tangent of the resin layer was calculated from the dielectric loss tangents and the film thicknesses of the samples A and B by the following expression. Furthermore, the samples A and B were used immediately after a humidity control for 24 hours in an environment of a temperature of 24° C. and a humidity of 50% RH.

Standard dielectric loss tangent of resin layer (Cured film of adhesive layer)={(Standard dielectric loss tangent of sample A×Film thickness [μm] of sample A)−(Standard dielectric loss tangent of sample B×Film thickness [μm] of sample B)}÷Film thickness [μm] of resin layer

<Peeling Strength Test>

Each laminate was cut into a strip in 1 cm×5 cm to manufacture a sample. A peel strength (unit: kN/m) of the obtained sample was measured according to the method for measuring a peel strength under normal conditions described in JIS C 6481. The peeling of the metal layer from the sample in a peel strength test was performed at an angle of 90° with respect to the sample and a peeling rate of 50 mm/sec.

In addition, specification of the peeling mode of the sample after the test was performed by visual observation of the peeled surface, evaluation of a change in film thickness, and confirmation on whether the resin layer was transferred to the polymer film or the metal layer side by measurement of the peeled surface using attenuated total reflection-infrared spectroscopy (ATR-IR), product name: Nicolet 6700 manufactured by Thermo Scientific Co., Ltd.). “Cohesive failure of LCP” means that the polymer film has cohesive failure. “Interfacial peeling of LCP/resin layer” means that interfacial peeling is performed between the polymer film and the resin layer. “Cohesive failure of resin layer” means that the resin layer has cohesive failure. In the case of “Cohesive failure of LCP”, it can be said that the metal layer is sufficiently attached.

<Evaluation Results>

The results of the evaluation test are shown in Table 1 below.

The addition amount in the column of “Adhesive layer” in Table 1 means the amount of a solid content.

In addition, in each of Examples and Comparative Examples, the thickness of the adhesive layer and the thickness of the resin layer obtained by curing the adhesive layer were the same.

Moreover, the standard dielectric loss tangent of the polymer film in each of Examples and Comparative Examples was the same as the standard dielectric loss tangent of the liquid crystal polymer included in the polymer film.

TABLE 1

| | | | | | | Adhesive layer | | |
|---|---|---|---|---|---|---|---|---|
| | | | | | | Binder resin | | |
| | Polymer film | | | | | | Adition | |
| | | Film | Surface treatment | | Dielectric loss | | amount | |
| | | thickness | | Oxygen [symbol] | [symbol] of liquid | | [% be | Reactive compound |
| No. | Type | [μm] | Treatment | surface | crystal polymer | Material | mass] | Material |
| Example 1 | CTQ-25 | 25 | Atmospheric | 0.30 | 0.0022 | P [symbol] AD-200 | 95 | N,N-Diglycidyl-4-glycidyloxyaniline |
| | | | pressure plasma | | | (polyimide) | | (trifunctional epoxy) |
| Example 2 | CTQ-25 | 25 | Atmospheric | 0.30 | 0.0022 | P [symbol] AD-200 | 95 | N,N-Diglycidyl-4-glycidyloxyaniline |
| | | | pressure plasma | | | (polyimide) | | (trifunctional epoxy) |
| Example 3 | CTQ-25 | 25 | Atmospheric | 0.30 | 0.0022 | P [symbol] AD-200 | 95 | N,N-Diglycidyl-4-glycidyloxyaniline |
| | | | pressure plasma | | | (polyimide) | | (trifunctional epoxy) |
| Example 4 | CTQ-25 | 25 | Atmospheric | 0.30 | 0.0022 | P [symbol] AD-200 | 85 | N,N-Diglycidyl-4-glycidyloxyaniline |
| | | | pressure plasma | | | (polyimide) | | (trifunctional epoxy) |
| Example 5 | CTQ-25 | 25 | Atmospheric | 0.30 | 0.0022 | P [symbol] AD-200 | 80 | N,N-Diglycidyl-4-glycidyloxyaniline |
| | | | pressure plasma | | | (polyimide) | | (trifunctional epoxy) |
| Example 6 | CTQ-25 | 25 | Comma | 0.29 | 0.0022 | P [symbol] AD-200 | 95 | N,N-Diglycidyl-4-glycidyloxyaniline |
| | | | | | | (polyimide) | | (trifunctional epoxy) |
| Example 7 | CTQ-25 | 25 | Atmospheric | 0.30 | 0.0022 | P [symbol] AD-200 | 95 | 4-t-Butylphenylglycidyl ether |
| | | | pressure plasma | | | (polyimide) | | (monofunctional epoxy) |
| Example 8 | CTQ-25 | 25 | Atmospheric | 0.30 | 0.0022 | P [symbol] AD-200 | 95 | Cabod [symbol] |
| | | | pressure plasma | | | (polyimide) | | ( [symbol] ) |
| Example 9 | CTQ-25 | 25 | Atmospheric | 0.30 | 0.0022 | P [symbol] AD-200 | 95 | 3,3′,4,4′-Benzophen [symbol] carboxylic |
| | | | pressure plasma | | | (polyimide) | | di [symbol] |
| | | | | | | | | (trifunctional carboxylic anhydride) |
| Comparative | CTQ-25 | 25 | None | 0.25 | 0.0021 | P [symbol] AD-200 | 95 | N,N-Diglycidyl-4-glycidyloxyaniline |
| Example 1 | | | | | | (polyimide) | | (trifunctional epoxy) |
| Comparative | CTQ-25 | 25 | Atmospheric | 0.30 | 0.0022 | P [symbol] AD-200 | 100 | None |
| Example 2 | | | pressure plasma | | | (polyimide) | | |
| Comparative | CTQ-25 | 25 | Atmospheric | 0.30 | 0.0022 | P [symbol] AD-200 | 60 | N,N-Diglycidyl-4-glycidyloxyaniline |
| Example 3 | | | pressure plasma | | | (polyimide) | | (trifunctional epoxy) |
| Comparative | CTQ-25 | 25 | Atmospheric | 0.30 | 0.0022 | P [symbol] AD-200 | 95 | N,N-Diglycidyl-4-glycidyloxyaniline |
| Example 4 | | | pressure plasma | | | (polyimide) | | (trifunctional epoxy) |

| | Adhesive layer | | | | | | | | |
|---|---|---|---|---|---|---|---|---|---|
| | Reactive compound | | | | | | Dielectric | | |
| | Addition | | | | Metal layer | | loss [symbol] | | |
| | amount | Film | [symbol] curing | [symbol] | | Film | of polymer | Peel | |
| | [% by | thickness | dielectric | molules | Product | thickness | film and | strength | |
| No. | mass] | [μm] | loss [symbol] | [GPa] | name | [μm] | resin layer | [kN/m] | [symbol] |
| Example 1 | 5 | 0.8 | 0.0085 | 1.3 | CF-T9DA- | 18 | 0.00224 | 0.60 | Cohesive failure |
| | | | | | SV-18 | | | | of LCP |
| Example 2 | 5 | 0.2 | 0.0085 | 1.3 | CF-T9DA- | 18 | 0.00221 | 0.59 | Cohesive failure |
| | | | | | SV-18 | | | | of LCP |
| Example 3 | 5 | 0.1 | 0.0035 | 1.3 | CF-T9DA- | 18 | 0.00221 | 0.53 | Cohesive failure |
| | | | | | SV-18 | | | | of LCP |
| Example 4 | 15 | 0.8 | 0.0067 | 1.1 | CF-T9DA- | 18 | 0.00234 | 0.63 | Cohesive failure |
| | | | | | SV-18 | | | | of LCP |
| Example 5 | 20 | 0.8 | 0.0080 | 0.9 | CF-T9DA- | 18 | 0.00238 | 0.63 | Cohesive failure |
| | | | | | SV-18 | | | | of LCP |
| Example 6 | 5 | 0.8 | 0.0035 | 1.3 | CF-T9DA- | 18 | 0.00234 | 0.60 | Cohesive failure |
| | | | | | SV-18 | | | | of LCP |
| Example 7 | 5 | 0.8 | 0.0024 | 1.3 | CF-T9DA- | 18 | 0.00221 | 0.59 | Cohesive failure |
| | | | | | SV-18 | | | | of LCP |
| Example 8 | 5 | 0.8 | 0.00 [symbol] | 1.3 | CF-T9DA- | 18 | 0.00223 | 0.52 | Cohesive failure |
| | | | | | SV-18 | | | | of LCP |
| Example 9 | 5 | 0.8 | 0.00 [symbol] | 1.3 | CF-T9DA- | 18 | 0.00223 | 0.51 | Cohesive failure |
| | | | | | SV-18 | | | | of LCP |
| Comparative | 5 | 0.8 | 0.00 [symbol] 5 | 1.3 | CF-T9DA- | 18 | 0.00214 | 0.09 | Interface peeling |
| Example 1 | | | | | SV-18 | | | | of LCP/resin layer |
| Comparative | 0 | 0.8 | 0.00 [symbol] 5 | 1.4 | CF-T9DA- | 18 | 0.00218 | 0.12 | Interface peeling |
| Example 2 | | | | | SV-18 | | | | of LCP/resin layer |
| Comparative | 40 | 0.8 | 0.0140 | 0.6 | CF-T9DA- | 18 | 0.002 [symbol] 7 | 0.21 | Cohesive failure |
| Example 3 | | | | | SV-18 | | | | of LCP |
| Comparative | 5 | 8 | 0.0085 | 1.3 | CF-T9DA- | 18 | 0.00252 | 0.59 | Cohesive failure |
| Example 4 | | | | | SV-18 | | | | of LCP |

[symbol]

indicates data missing or illegible when filed

As seen in Table 1, it is shown that it is possible to form a laminate having an excellent adhesiveness of the metal layer and a low dielectric loss tangent of a portion other than the metal layer by using the polymer film with an adhesive layer of the embodiment of the present invention (Examples 1 to 9).

From the comparison between Examples 1 and 7 to 9, it is shown that in a case where the reactive compound having an epoxy group was used (Examples 1 and 7), the adhesiveness of the metal layer was more excellent.

From the comparison between Examples 1 and 7, it was shown that in a case where the reactive compound having three or more reactive groups was used (Example 1), the adhesiveness of the metal layer was more excellent.

What is claimed is:

1. A polymer film with an adhesive layer, comprising:
a polymer film including a polymer having a dielectric loss tangent under conditions of a temperature of 23° C. and a frequency of 28 GHz of 0.005 or less; and
the adhesive layer arranged on the polymer film,
wherein in a case where a surface of the polymer film on a side of the adhesive layer is measured by X-ray photoelectron spectroscopy, an atomic ratio of oxygen atoms to carbon atoms is 0.27 or more,
the adhesive layer includes a compound having a reactive group,
the adhesive layer has a thickness of 1 μm or less, and
the adhesive layer has a post-curing elastic modulus of 0.8 GPa or more.

2. A polymer film with an adhesive layer, comprising:
a polymer film having a dielectric loss tangent under conditions of a temperature of 23° C. and a frequency of 28 GHz of 0.005 or less; and
the adhesive layer arranged on the polymer film,
wherein in a case where a surface of the polymer film on a side of the adhesive layer is measured by X-ray photoelectron spectroscopy, an atomic ratio of oxygen atoms to carbon atoms is 0.27 or more,
the adhesive layer includes a compound having a reactive group,
the adhesive layer has a thickness of 1 μm or less, and
the adhesive layer has a post-curing elastic modulus of 0.8 GPa or more.

3. The polymer film with an adhesive layer according to claim 1,
wherein the reactive group is at least one group selected from the group consisting of an epoxy group, an oxetanyl group, an isocyanate group, an acid anhydride group, a carbodiimide group, an N-hydroxyester group, a glyoxal group, an imidoester group, an alkyl halide group, and a thiol group.

4. The polymer film with an adhesive layer according to claim 1,
wherein the adhesive layer has a post-curing dielectric loss tangent under the conditions of a temperature of 23° C. and a frequency of 28 GHz of 0.01 or less.

5. The polymer film with an adhesive layer according to claim 1,
wherein the adhesive layer has a post-curing elastic modulus of 1.2 GPa or more.

6. The polymer film with an adhesive layer according to claim 1,
wherein the adhesive layer further includes a binder resin.

7. The polymer film with an adhesive layer according to claim 1,
wherein the compound having a reactive group has three or more of the reactive groups.

8. A laminate comprising:
a polymer film including a polymer having a dielectric loss tangent under conditions of a temperature of 23° C. and a frequency of 28 GHz of 0.005 or less;
a resin layer arranged on the polymer film; and
a metal layer arranged on the resin layer,
wherein in a case where a surface of the polymer film on a side of the resin layer is measured by X-ray photoelectron spectroscopy, an atomic ratio of oxygen atoms to carbon atoms is 0.27 or more,
the resin layer has a thickness of 1 μm or less, and
the resin layer has an elastic modulus of 0.8 GPa or more.

9. A laminate comprising:
a polymer film having a dielectric loss tangent under conditions of a temperature of 23° C. and a frequency of 28 GHz of 0.005 or less;
a resin layer arranged on the polymer film; and
a metal layer arranged on the resin layer,
wherein in a case where a surface of the polymer film on a side of the resin layer is measured by X-ray photoelectron spectroscopy, an atomic ratio of oxygen atoms to carbon atoms is 0.27 or more,
the resin layer has a thickness of 1 μm or less, and
the resin layer has an elastic modulus of 0.8 GPa or more.

10. The laminate according to claim 8,
wherein a maximum height Rz of a surface of the metal layer on a side of the resin layer is 0.6 to 2.0 μm.

11. The laminate according to claim 8,
wherein the resin layer has a dielectric loss tangent under the conditions of a temperature of 23° C. and a frequency of 28 GHz of 0.01 or less.

12. The laminate according to claim 8,
wherein the resin layer has an elastic modulus of 1.2 GPa or more.

13. A method for producing the laminate according to claim 8, the method comprising:
a step of attaching a composition for forming an adhesive layer, including a compound having a reactive group, onto a polymer film to obtain a polymer film with the adhesive layer, in which the adhesive layer is arranged on the polymer film; and
a step of arranging a metal foil on the adhesive layer in the polymer film with the adhesive layer, and thermocompression-bonding the adhesive layer and the metal foil to each other to form a metal layer on a resin layer obtained by curing the adhesive layer.

14. The polymer film with an adhesive layer according to claim 2,
wherein the reactive group is at least one group selected from the group consisting of an epoxy group, an oxetanyl group, an isocyanate group, an acid anhydride group, a carbodiimide group, an N-hydroxyester group, a glyoxal group, an imidoester group, an alkyl halide group, and a thiol group.

15. The polymer film with an adhesive layer according to claim 2,
wherein the adhesive layer has a post-curing dielectric loss tangent under the conditions of a temperature of 23° C. and a frequency of 28 GHz of 0.01 or less.

16. The polymer film with an adhesive layer according to claim 2,
wherein the adhesive layer has a post-curing elastic modulus of 1.2 GPa or more.

17. The polymer film with an adhesive layer according to claim 2,
wherein the adhesive layer further includes a binder resin.

18. The polymer film with an adhesive layer according to claim 2,
wherein the compound having a reactive group has three or more of the reactive groups.

19. The laminate according to claim 9,
wherein a maximum height Rz of a surface of the metal layer on a side of the resin layer is 0.6 to 2.0 μm.

20. The laminate according to claim 9,
wherein the resin layer has a dielectric loss tangent under the conditions of a temperature of 23° C. and a frequency of 28 GHz of 0.01 or less.
